(19) United States
(12) Patent Application Publication
(10) Pub. No.: US 2025/0366068 A1
(43) Pub. Date: Nov. 27, 2025

(54) SEMICONDUCTOR DEVICE HAVING NANOSTRUCTURE TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Chih-Hao WANG, Hsinchu County (TW); Guan-Lin CHEN, Hsinchu County (TW); Hsien-Chih HUANG, Hsinchu (TW); Chia-Hao YU, New Taipei City (TW); Pei-Yu WANG, Hsinchu City (TW)

(21) Appl. No.: 19/293,129

(22) Filed: Aug. 7, 2025

Related U.S. Application Data
(63) Continuation of application No. 18/642,872, filed on Apr. 23, 2024.
(60) Provisional application No. 63/606,406, filed on Dec. 5, 2023.

(51) Int. Cl. H10D 30/67; H01L 21/02; H10D 30/01; H10D 30/43; H10D 62/10; H10D 62/13; H10D 64/01; H10D 84/01; H10D 84/03; H10D 84/85

(52) U.S. Cl. CPC H10D 30/6757; H01L 21/02236; H01L 21/02532; H01L 21/02603; H01L 21/0262; H10D 30/014; H10D 30/43; H10D 30/6735; H10D 30/6741; H10D 62/121; H10D 62/151; H10D 64/017; H10D 84/0167; H10D 84/038; H10D 84/85

(57) ABSTRACT

Embodiments of the disclosure provide a semiconductor device structure including a first transistor comprising a plurality of first semiconductor layers vertically stacked, each first semiconductor layer being surrounded by a first gate electrode layer, a second transistor disposed over the first transistor, the second transistor comprising a plurality of second semiconductor layers vertically stacked, each second semiconductor layer being surrounded by a second gate electrode layer different from the first gate electrode layer, an isolation layer disposed between a topmost first semiconductor layer of the first transistor and a bottommost second semiconductor layer of the second transistor, the isolation layer comprising a dielectric material, a first source/drain feature in contact with the first semiconductor layers and a portion of the isolation layer, and a second source/drain feature disposed over the first source/drain feature and in contact with the second semiconductor layers and a portion of the isolation layer, wherein the topmost first semiconductor layer and the bottommost second semiconductor layer comprise alkaline elements diffused from a sacrificial layer comprising a semiconductor metal oxide.

### CROSS-REFERENCE TO RELATED APPLICATIONS

This application is a continuation application of U.S. patent application Ser. No. 18/642,872 filed Apr. 23, 2024, which claims priority to U.S. Provisional Application Ser. No. 63/606,406 filed Dec. 5, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In pursuit of higher device density, higher performance, and lower costs, challenges from both fabrication and design issues have resulted in the development of three-dimensional designs, such as a multi-gate field effect transistor (FET), including a nanosheet FET. In a nanosheet FET, all side surfaces of the channel region are surrounded by the gate electrode, which allows for fuller depletion in the channel region and results in less short-channel effects due to steeper sub-threshold current swing (SS) and smaller drain induced barrier lowering (DIBL). As transistor dimensions are continually scaled down, further improvements of the nanosheet FET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure in accordance with some embodiments.

FIGS. 6A-16A are cross-sectional side views of various stages of manufacturing the semiconductor device structure taken along cross-section A-A of FIG. 5, in accordance with some embodiments.

FIGS. 6B-16B are cross-sectional side views of various stages of manufacturing the semiconductor device structure taken along cross-section B-B of FIG. 5, in accordance with some embodiments.

FIGS. 6C and 11C-16C are cross-sectional side views of various stages of manufacturing the semiconductor device structure taken along cross-section C-C of FIG. 5, in accordance with some embodiments.

FIGS. 6D and 11D-16D are cross-sectional side views of various stages of manufacturing the semiconductor device structure taken along cross-section D-D of FIG. 5, in accordance with some embodiments.

FIGS. 17 and 18 are perspective views of various stages of manufacturing a semiconductor device structure in accordance with some alternative embodiments.

FIGS. 19A and 19B to 22A and 22B are cross-sectional side views of various stages of manufacturing the semiconductor device structure taken along cross-section A-A of FIG. 18, in accordance with some alternative embodiments.

FIGS. 23A-23D to 24A-24D are cross-sectional side views of various stages of manufacturing the semiconductor device structure taken along cross-section A-A, cross-section B-B, cross-section C-C, and cross-section D-D of FIG. 18, in accordance with some alternative embodiments.

FIGS. 25A and 25B to 29A and 29B are cross-sectional side views of various stages of manufacturing the semiconductor device structure taken along cross-section A-A of FIG. 18, in accordance with some alternative embodiments.

FIGS. 30A-30D to 32A-32D are cross-sectional side views of various stages of manufacturing the semiconductor device structure taken along cross-section A-A, cross-section B-B, cross-section C-C, and cross-section D-D of FIG. 18, in accordance with some alternative embodiments.

FIGS. 33A and 33B to 37A and 37B are cross-sectional side views of various stages of manufacturing the semiconductor device structure taken along cross-section A-A of FIG. 18, in accordance with some alternative embodiments.

FIGS. 38A-38D to 40A-40D are cross-sectional side views of various stages of manufacturing the semiconductor device structure taken along cross-section A-A, cross-section B-B, cross-section C-C, and cross-section D-D of FIG. 18, in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

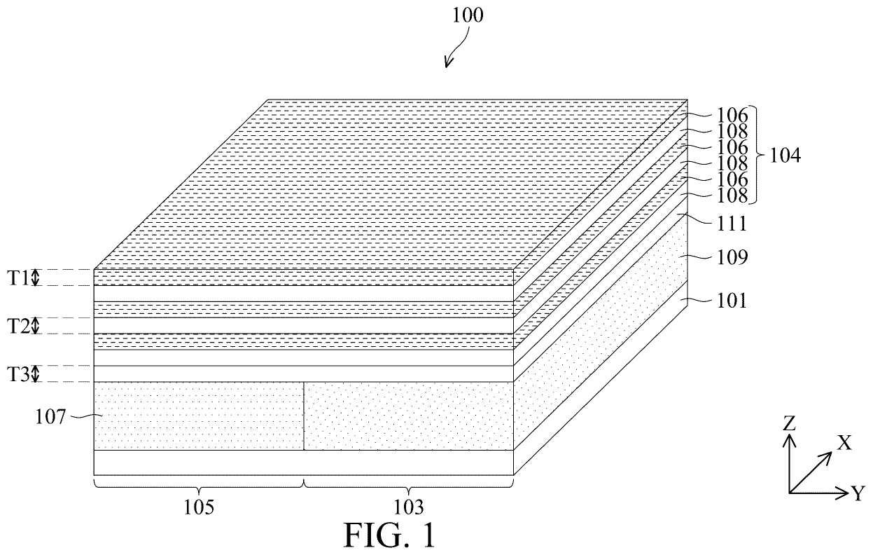

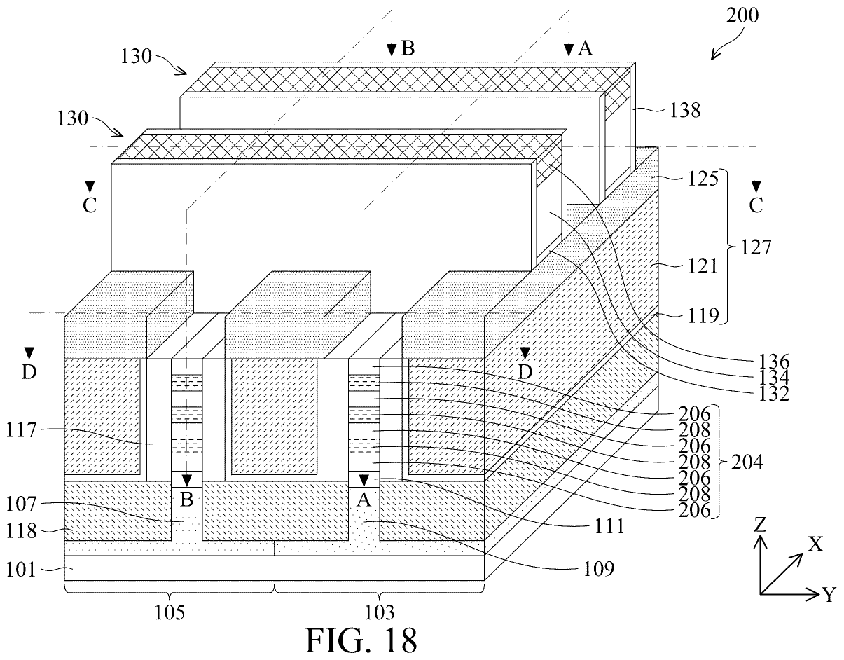

FIGS. 1 to 40D show exemplary processes for manufacturing a semiconductor device structure 100 according to embodiments of the present disclosure. It is understood that additional operations can be provided before, during, and after processes shown by FIGS. 1 to 40D, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 in accordance with some embodiments. With reference to FIG. 1, the semiconductor device structure 100 is illustrated to include a substrate 101 into which dopants have been implanted in order to form wells. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 may include a first device region 103 for forming N-type devices, such as NMOS devices (e.g., N-type gate all around transistors) and a second device region 105 for forming P-type devices, such as PMOS devices (e.g., P-type gate all around transistors). To distinguish between the first device region 103 and the second device region 105, wells may be formed within the substrate 101 with N-type dopants and P-type dopants. To form the desired wells, the N-type dopants and the P-type dopants are implanted into the substrate 101 depending upon the devices to be formed. For example, N-type dopants such as phosphorous or arsenic may be implanted to form N-type wells, while P-type dopants such as boron may be implanted to form P-type wells. The N-type wells and P-type wells may be formed using one or more implantation techniques, such as diffusion implantations, ion implantations (e.g., plasma doping, beam line implant doping), selective implantations, deep-well implantations, and the like, or combinations thereof. Masking techniques may also be utilized to mask some regions (e.g., second device region 105) of the substrate 101 while exposing other regions (e.g., first device region 103) of the substrate 101 during a first well implantation (e.g., N-type wells) process. Once the first well implantation process has been completed, the mask is removed to expose the previously masked regions (e.g., second device region 105) and another mask may be placed over the previously exposed regions (e.g., first device region 103) during a second well implantation (e.g., P-type wells) process. In one embodiment shown in FIG. 1, the substrate 101 includes an N-type well 107 and a P-type well 109. While the first device region 103 is shown adjacent to the second device region 105, it is understood that the first device region 103 may be disposed away from the second device region 105 at different regions of the substrate 101 along the X direction or Y direction, and the first and second device regions 103, 105 belong to a continuous substrate (e.g., substrate 101).

FIG. 1 also illustrates a stack of semiconductor layers 104 formed over the substrate 101 at the first and second device regions 103, 105. The stack of semiconductor layers 104 includes semiconductor layers made of different materials to facilitate formation of nanostructure channels in a multi-gate device, such as nanostructure FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a Ge concentration of about 30 at. % or above, such as about 35 at. % or above. In some embodiments, the first semiconductor layers 106 may be made of SiGe having a first Ge concentration range, and the second semiconductor layers 108 may be made of SiGe having a second Ge concentration range that is lower or greater than the first Ge concentration range. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The substrate 101 includes an etch stop layer 111 disposed between the stack of semiconductor layers 104 and the wells (e.g., first and second device regions 103, 105). The etch stop layer 111 serves as a blocking layer during the subsequent etching process for forming recess for source/drain features. The etch stop layer 111 may be made of SiGe having a Ge concentration of about 30 at. % or below, such as about 10 at. % to about 30 at. %. In cases where the first semiconductor layers 106 or the second semiconductor layers 108 is formed of SiGe, the etch stop layer 111 may have a Ge concentration different than (e.g., smaller than) the Ge concentration of the first semiconductor layers 106 or the second semiconductor layers 108. In one exemplary embodiment shown in FIG. 1, the first semiconductor layers 106 include SiGe having a Ge concentration of about 35 at. % or above, the second semiconductor layers 108 include Si, and the etch stop layer 111 includes SiGe having a Ge concentration of about 30 at. % or below.

The thickness of the first semiconductor layers 106, the second semiconductor layers 108, and the etch stop layer 111 may vary depending on the application and/or device performance considerations. In some embodiments, each first and second semiconductor layer 106, 108 has a thickness T1, T2 of about 2 nm to about 30 nm, respectively, and the etch stop layer 111 has a thickness T3 of about 2 nm to about 30 nm. In other embodiments, each first and second semiconductor layer 106, 108 has a thickness T1, T2 of about 10 nm to about 20 nm, and the etch stop layer 111 has a thickness T3 of about 10 nm to about 20 nm. The thickness T1 of the first semiconductor layer 106 may be equal to, less than, or greater than the thickness of the thickness T2 of the second semiconductor layer 108. The thickness T3 may be equal to, less than, or greater than the thickness T1, T2. In one exemplary embodiment, the etch stop layer 111 and each first semiconductor layer 106 may have a thickness of about 4 nm to about 8 nm.

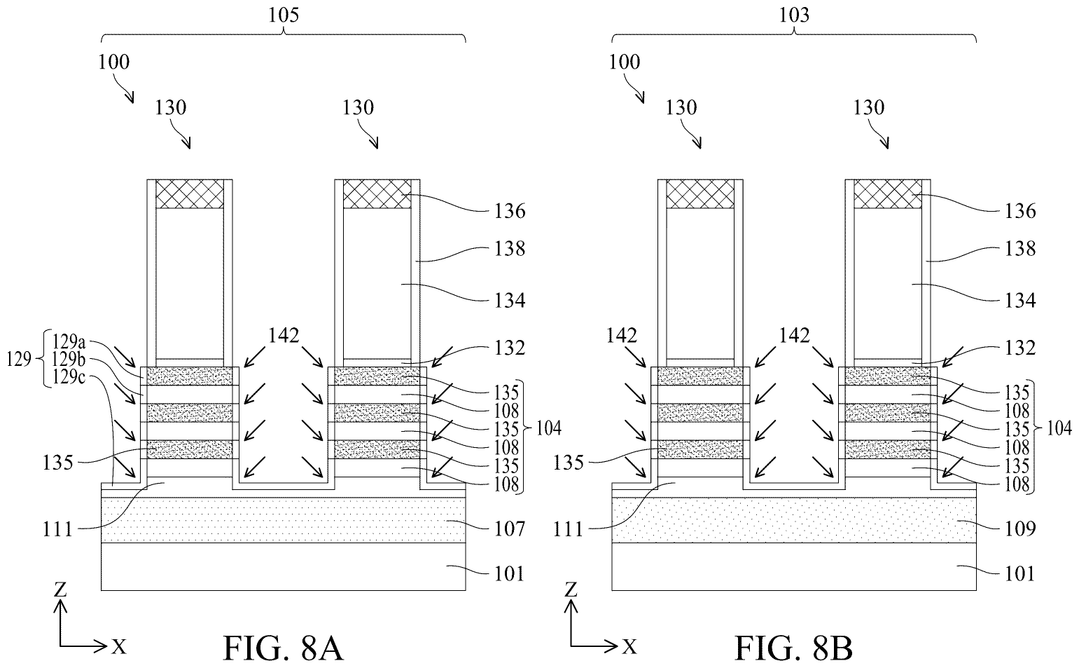

As will be discussed in more detail below, the first semiconductor layers 106 or the second semiconductor layers 108 may eventually be removed and serve to define a vertical distance between adjacent channels for the semiconductor device structure 100. If the first semiconductor layers 106 is too thick, the subsequently formed Ge channel layers (e.g., filling layers 135, FIGS. 8A and 8B) may be too thick and diminish the effectiveness of the gate control. If the first semiconductor layers 106 is too thin, the process window of forming the subsequent Ge channel layers may be narrow. In addition, if the thickness of the etch stop layer 111 is too thick, there may be lattice mismatch issue which in turn introduces defects such as dislocation to the channel layers and/or adjacent layers. If the etch stop layer 111 is too thin, it may not function properly as a stop layer during the subsequent etching process for forming recess for source/drain features.

The first or second semiconductor layers 106, 108 or portions thereof may form nanostructure channel(s) of the semiconductor device structure 100 in later fabrication stages. The term “nanostructure” is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanowire transistors, nanosheet transistors, gate-all-around (GAA) transistors, multi-bridge channel (MBC) transistors, or any transistors having the gate electrode surrounding the channels. The use of the first semiconductor layers 106 to define channels of the semiconductor device structure 100 is further discussed below.

The first and second semiconductor layers 106, 108 as well as the etch stop layer 111 are formed by any suitable deposition process, such as epitaxy. By way of example, epitaxial growth of the layers of the stack of semiconductor layers 104 may be performed by a vapor-phase epitaxy (VPE), a molecular beam epitaxy (MBE) process, a metalorganic chemical vapor deposition (MOCVD) process, and/or other suitable growth processes, such as chemical vapor deposition (CVD), low pressure CVD (LPCVD), atomic layer CVD (ALCVD), ultra-high vacuum CVD (UHVCVD), reduced pressure CVD (RPCVD), a combination thereof, or the like. While three first semiconductor layers 106 and three second semiconductor layers 108 are alternately arranged as illustrated in FIG. 1, any number of first and second semiconductor layers 106, 108 can be formed in the stack of semiconductor layers 104, depending on the predetermined number of nanostructure channels for each FET. For example, the number of first semiconductor layers 106, which is the number of channels, may be between 2 and 8.

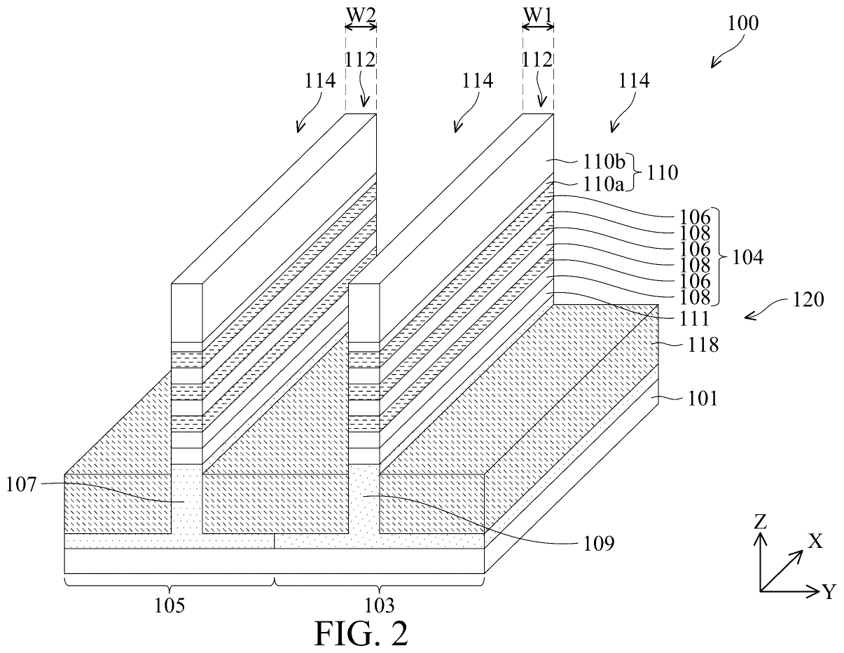

In FIG. 2, fin structures 112 are formed from the stack of semiconductor layers 104, and an insulating material 118 is formed in the trenches 114 between the fin structures 112. Each fin structure 112 has a portion including the semiconductor layers 106, 108, a portion of the wells 107, 109, and a portion of a mask structure 110. The mask structure 110 is formed over the stack of semiconductor layers 104 prior to forming the fin structures 112. The mask structure 110 may include a pad layer 110a and a hard mask 110b. The pad layer 110a may be an oxygen-containing layer. The hard mask 110b may be a nitrogen-containing layer. The fin structures 112 may be fabricated using suitable processes including photolithography and etch processes. In some embodiments, the photolithography process may include forming a photoresist layer (not shown) over the mask structure 110, exposing the photoresist layer to a pattern, performing post-exposure bake processes, and developing the photoresist layer to form a patterned photoresist layer. The patterned photoresist layer may then be used to protect regions of the substrate 101 and layers formed thereupon, while an etch process forms trenches 114 in unprotected regions through the mask structure 110, the stack of semiconductor layers 104, and into the wells 107, 109 of the substrate 101, thereby forming the extending fin structures 112. A width W1 of the fin structures 112 at the first device region 103 along the Y direction may be in a range between about 3 nm and about 44 nm. A width W2 of the fin structures 112 at the second device region 105 along the Y direction may be equal to, less than, or greater than the width W1. The trenches 114 may be etched using a dry etch (e.g., RIE), a wet etch, and/or combination thereof. While two fin structures 112 are shown, the number of the fin structures is not limited to two.

After the fin structures 112 are formed, the insulating material 118 is formed in the trenches 114 between the fin structures 112. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as LPCVD, plasma enhanced CVD (PECVD) or flowable CVD (FCVD). Next, the insulating material 118 is recessed to form an isolation region 120. The recess of the insulating material 118 exposes portions of the fin structures 112. The isolation region 120 may be formed using a suitable process, such as a dry etching process, a wet etching process, or a combination thereof. A top surface of the insulating material 118 may be level with or below a surface of the second semiconductor layer 108 in contact with the wells 107, 109.

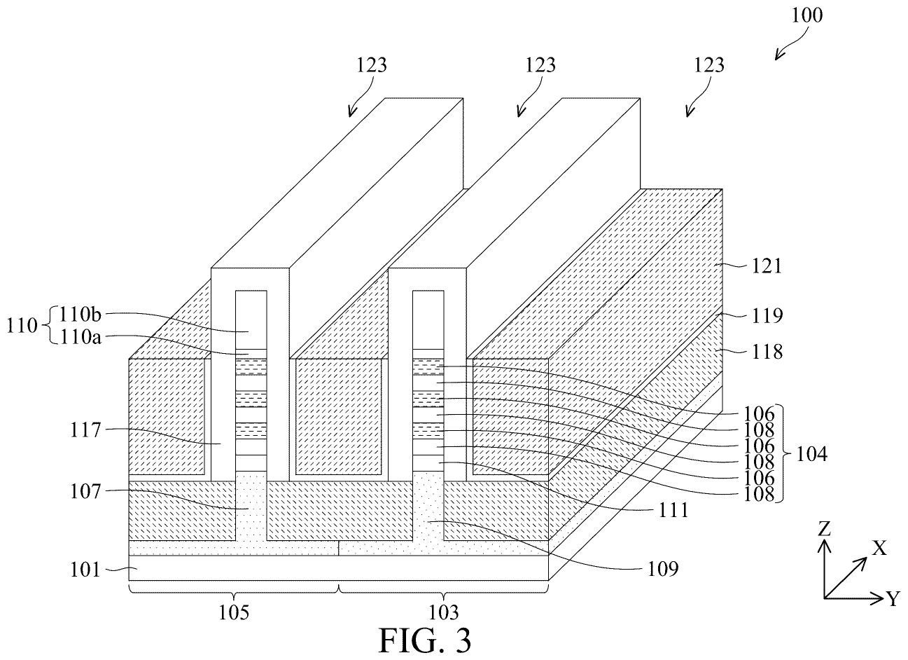

In FIG. 3, a cladding layer 117 is formed over exposed portion of the fin structures 112. The cladding layer 117 is in contact with the stack of semiconductor layers 104. In some embodiments, the cladding layer 117 and the second semiconductor layers 108 include the same material. For example, the cladding layer 117 and the second semiconductor layers 108 may be or include silicon. The cladding layer 117 and the second semiconductor layers 108 are to be removed subsequently to create space for the subsequently formed gate electrode layer. A liner 119 is formed on the cladding layer 117 and the top surface of the insulating material 118. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 2) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112 (FIG. 2).

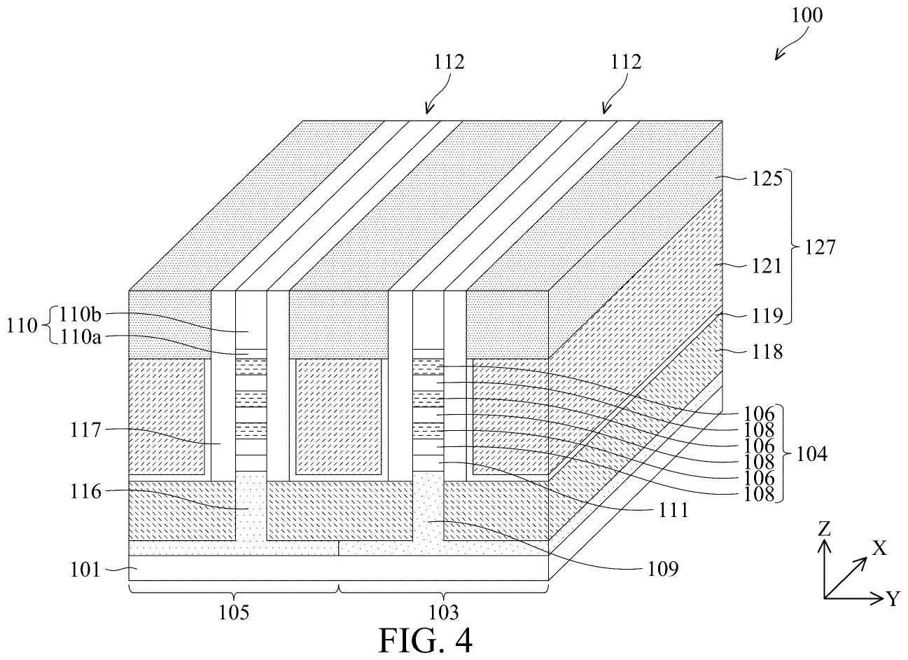

In FIG. 4, a dielectric material 125 is formed in the trenches 123 (FIG. 3) and on the dielectric material 121 and the liner 119. The dielectric material 125 may include SiO, SiN, SiC, SiCN, SiON, SiOCN, AlO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequently formed source/drain (S/D) epitaxial features and adjacent gate electrode layers.

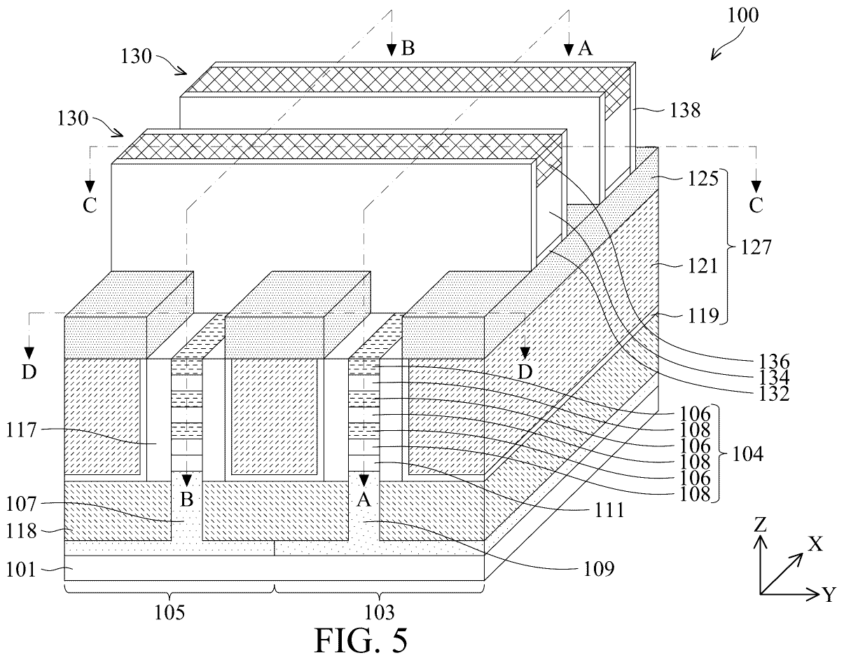

In FIG. 5, the cladding layers 117 are recessed, and the mask structures 110 are removed. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

Thereafter, one or more sacrificial gate structures 130 are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. While two sacrificial gate structures 130 are shown, three or more sacrificial gate structures 130 may be arranged along the X direction in some embodiments.

FIG. 5 also illustrates that gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100 by an ALD process or any suitable conformal deposition technique. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as SiO₂, Si₃N₄, SiC, SiON, SiCN, SiOCN, carbon doped oxide, nitrogen doped oxide, porous oxide, air gaps, and/or combinations thereof.

It should be understood that the cladding layers 117 and dielectric feature 127 (i.e., hybrid fin) are optional and may not be needed. In some embodiments where the cladding layers 117 and the dielectric features 127 are not present, portions of the sacrificial gate structures 130 and the gate spacers 138 are formed on the fin structures 112 and the insulating material 118, and gaps are formed between exposed portions of the fin structures 112.

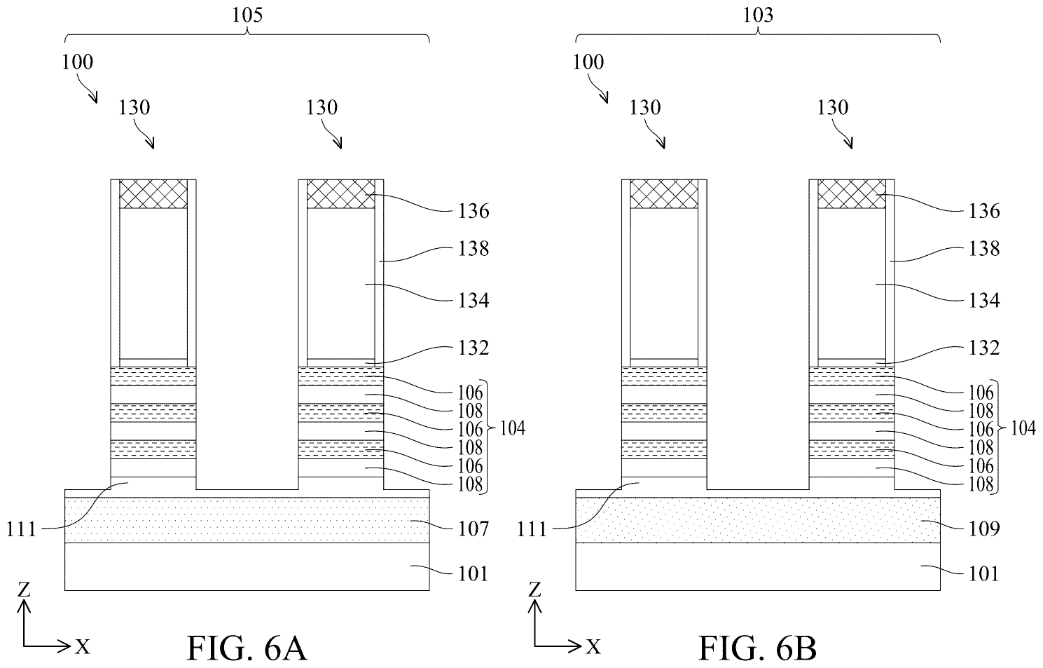

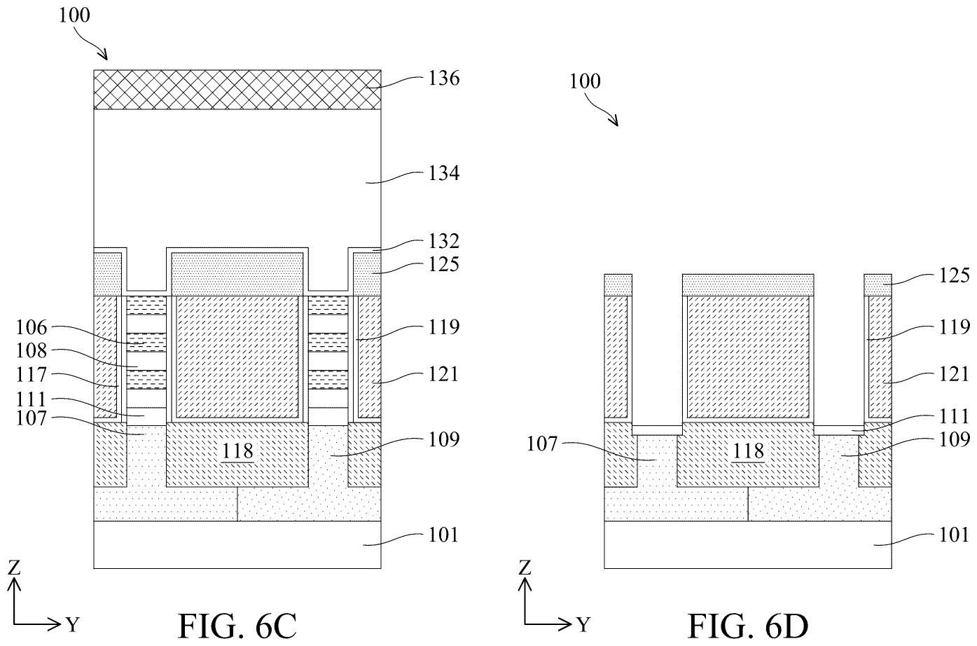

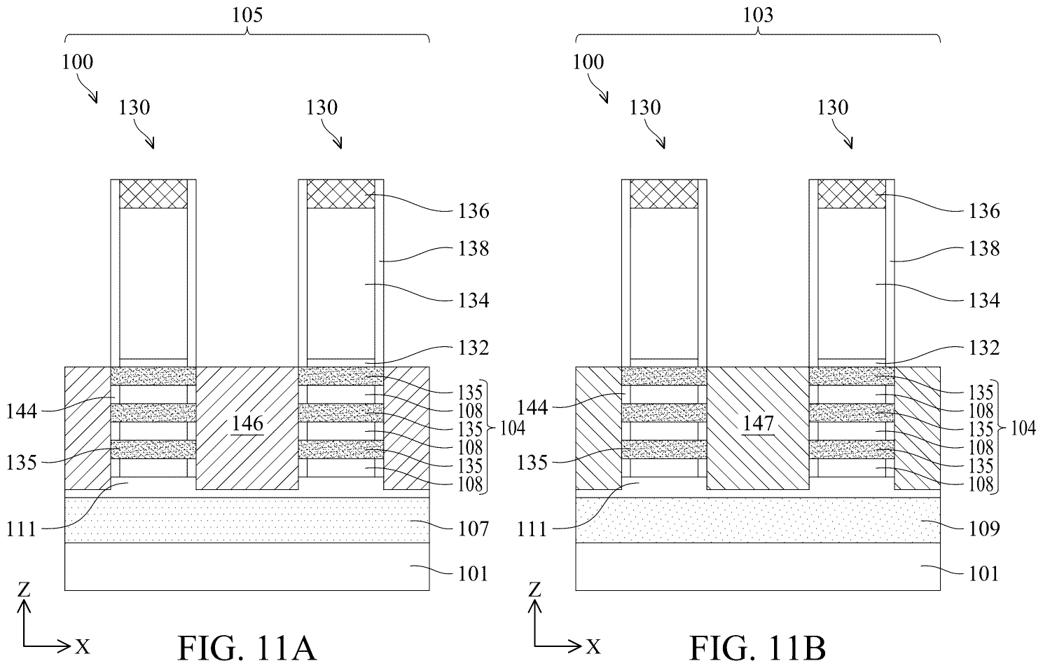

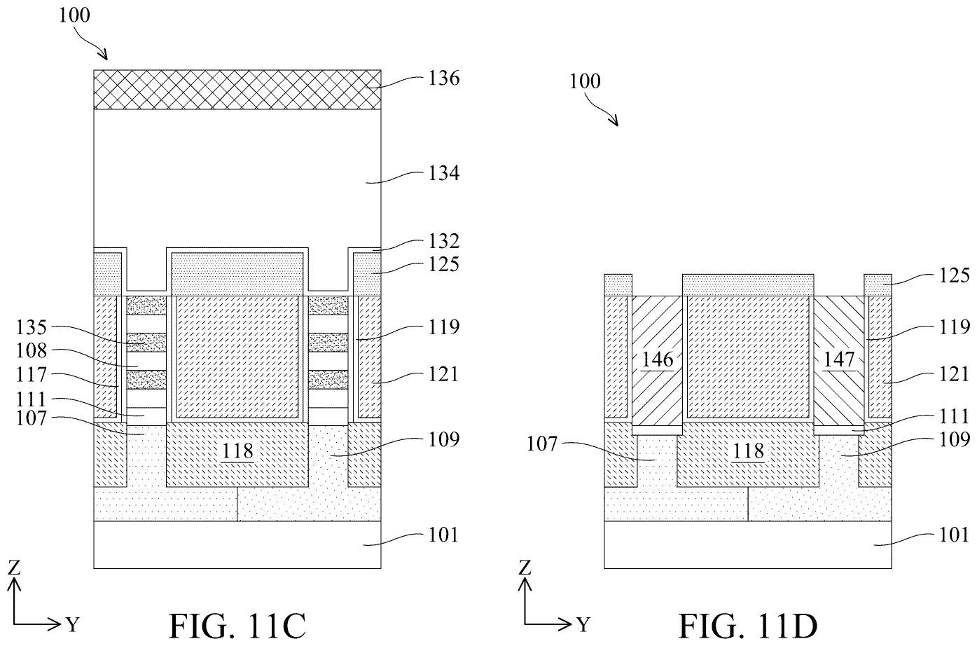

FIGS. 6A-16A are cross-sectional side views of various stages of manufacturing the semiconductor device structure 100 taken along cross-section A-A of FIG. 5, in accordance with some embodiments. FIGS. 6B-16B are cross-sectional side views of various stages of manufacturing the semiconductor device structure 100 taken along cross-section B-B of FIG. 5, in accordance with some embodiments. FIGS. 6C and 11C-16C are cross-sectional side views of various stages of manufacturing the semiconductor device structure 100 taken along cross-section C-C of FIG. 5, in accordance with some embodiments. FIGS. 6D and 11D-16D are cross-sectional side views of various stages of manufacturing the semiconductor device structure 100 taken along cross-section D-D of FIG. 5, in accordance with some embodiments. Cross-sections A-A and B-B are in a plane of the fin structure 112 (FIG. 4) along the X direction. Cross-section C-C is in a plane perpendicular to cross-section A-A and is in the sacrificial gate structure 130. Cross-section D-D is in a plane perpendicular to cross-section A-A and is in the S/D features 146 (FIGS. 11A and 11B) along the Y-direction.

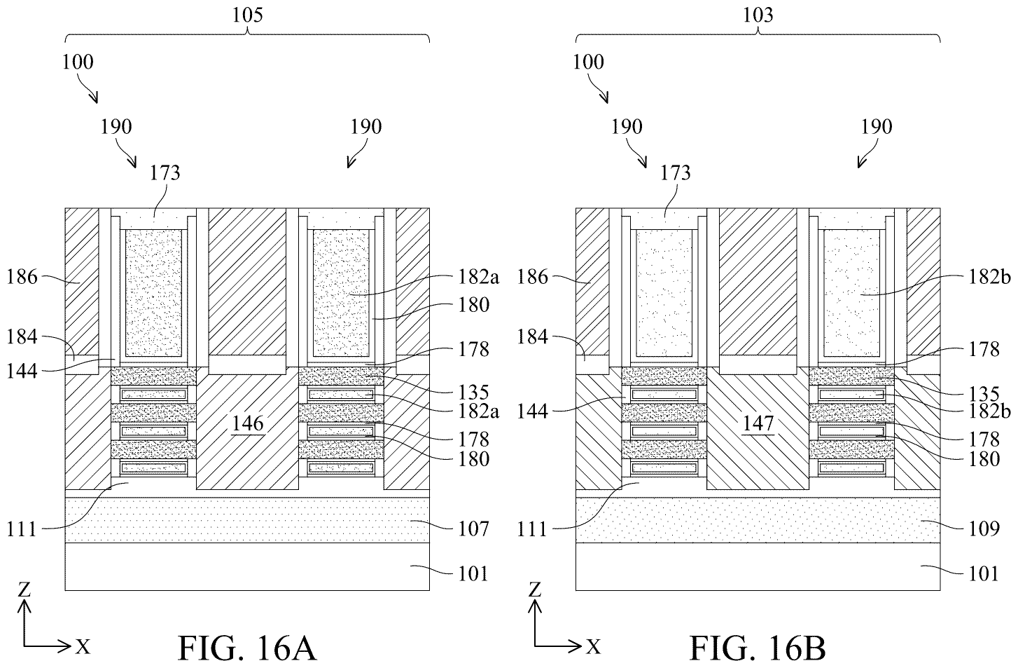

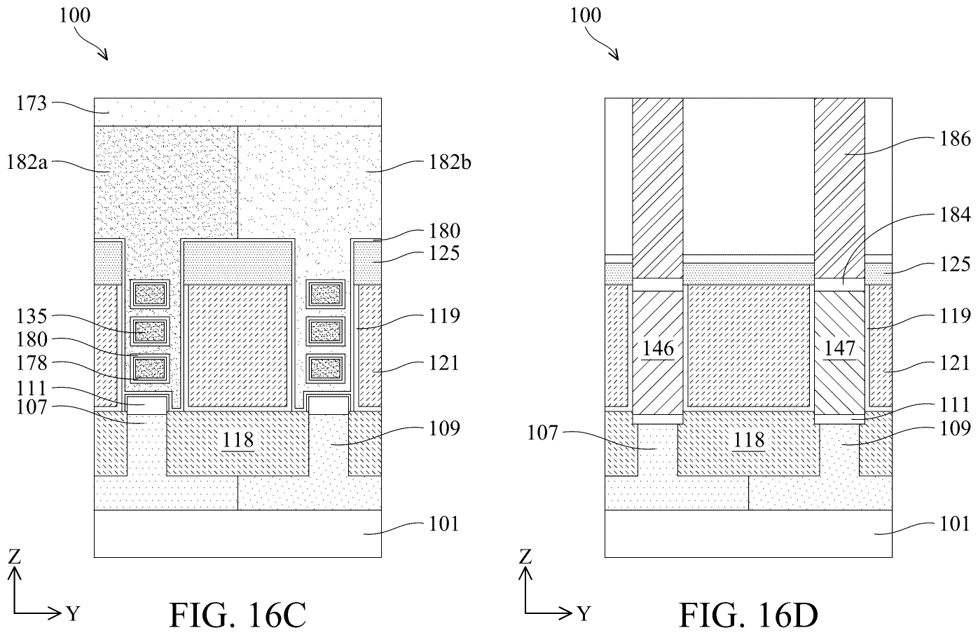

In FIGS. 6A-6D, exposed portions of the fin structures 112, the cladding layers 117, and the dielectric material 125 at the first and second device regions 103, 105 not covered by the sacrificial gate structures 130 and the gate spacers 138 are recessed to form source/drain (S/D) regions. The removal process may include one or more suitable etch processes, such as dry etch, wet etch, or a combination thereof. The portions of the fin structures 112, the cladding layers 117, and the dielectric material 125 are removed to expose the sidewalls of the fin structures 112 (FIG. 4). In some embodiments, the removal process is performed so that the sidewalls of the bottommost second semiconductor layer 108 of each fin structure 112 are fully exposed and a sidewall of the etch stop layer 111 is exposed. In some embodiments, the removal process is performed such that a top surface 111t of the etch stop layer 111 is etched to have a curved profile (e.g., concave), such as the embodiment shown in FIG. 16D.

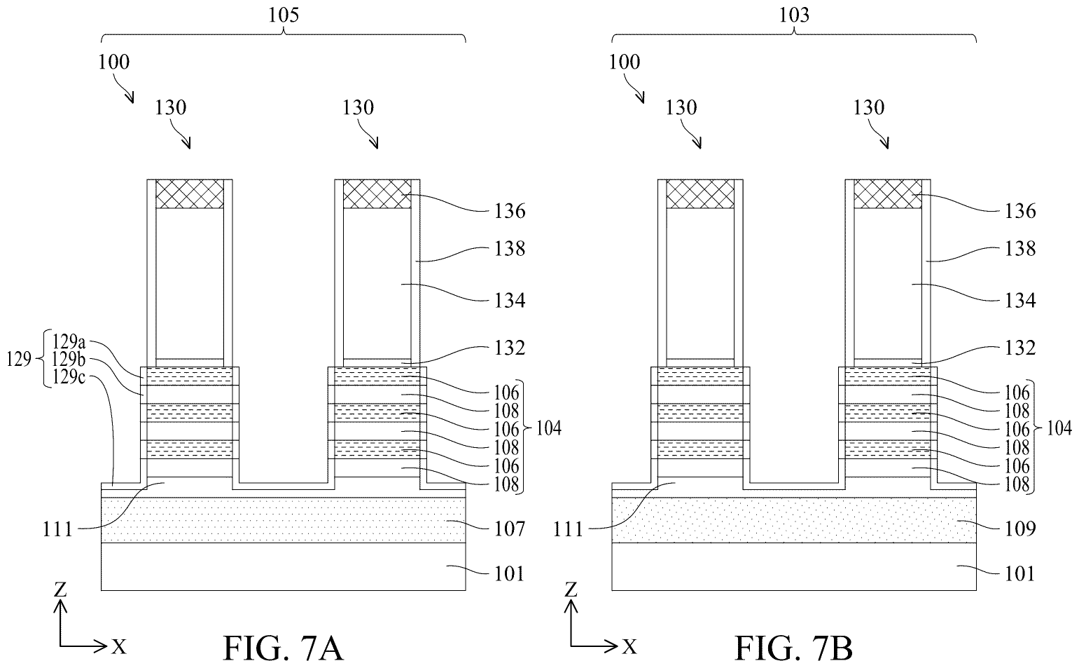

In FIGS. 7A and 7B, oxide layers 129a, 129b, 129c (collectively referred to as oxide layer 129) are formed on the exposed surfaces of the first semiconductor layers 106, the second semiconductor layers 108, and the etch stop layer 111, respectively. The oxide layers 129a, 129b, 129c may be formed as a result of a cleaning process and a post-treatment process. The cleaning process may be any suitable wet etch process that transforms surface portions of the first semiconductor layers 106, the second semiconductor layers 108, and the etch stop layer 111 into an oxide layer. In cases where the first semiconductor layers 106 include SiGe having higher atomic concentration of Ge (e.g., about 35 at. % or greater), the second semiconductor layers 108 include Si, and the etch stop layer 111 includes SiGe having lower atomic concentration of Ge (e.g., about 30 at. % or lower), the oxide layer 129a formed on the surface of the first semiconductor layers 106 may include silicon germanium oxide (SiGeO) with a greater amount of Ge, and the oxide layer 129b formed on the surface of the second semiconductor layers 108 may include silicon oxide (SiO), and the oxide layer 129c formed on the surface of the etch stop layer 111 may include SiGeO with a lesser amount of Ge, respectively. The post-treatment process may be any suitable etch process that selectively removes Ge from SiGeO. The removal of germanium from the oxide layers 129a and 129c results in oxide layers 129a, 129b, 129c with different film qualities. For example, the oxide layer 129a may become a porous SiO as compared to the oxide layer 129b, and the oxide layer 129c may become a slightly porous SiO as compared to the oxide layer 129b. As will be discussed in more detail below, the greater porosity of the oxide layer 129a allows easy replacement of SiGe with Ge at a later stage.

The oxide layer 129 may have a thickness in a range between about 5 Å and about 10 Å. If the thickness of the oxide layer 129 is below about 5 Å, the oxide layer 129 may not be thick enough to function as its intended purpose. If the thickness of the oxide layer 129 is greater than about 10 Å, the chemical gas may have trouble passing through.

In FIGS. 8A and 8B, the first semiconductor layers 106 is removed, and a filling layer 135 is refilled in the region where the first semiconductor layers 106 were removed. The filling layer 135 functions as a channel layer for PMOS and NMOS devices, and may be made of a semiconductor material. In one embodiment, the filling layer 135 is formed of germanium (e.g., pure Ge). Germanium has attracted attention as the most promising candidate for next-generation material because it has higher carrier mobility than silicon and is larger in atomic radius than silicon. Due to lattice mismatch between germanium and silicon, using germanium as a material for the filling layer 135 will produce strain (i.e., strained germanium) and thus enhance channel mobility for transistor devices, particularly the PMOS devices (e.g., P-type gate all around transistors). While germanium is discussed, other semiconductor materials having an atomic radius greater (e.g., about 0.5 times to about 1.5 times greater) than the atomic radius of the chemical element used for the second semiconductor layers 108 (e.g., silicon), may also be used. Suitable materials for the filling layer 135 may include, but are not limited to, gallium (Ga), indium (In), tin (Sn), selenium (Se), antimony (Sb), etc.

The removal of the first semiconductor layers 106 may be done by exposing the semiconductor device structure 100 to an etching gas that is adapted to selectively remove SiGe without substantially affecting SiO. Since the oxide layer 129a is porous, the etching gas can easily flow through the oxide layer 129a and remove the first semiconductor layers 106 without removing the oxide layer 129a. Thereafter, the semiconductor device structure 100 is exposed to a deposition gas 142 to epitaxially grow the filling layer 135 in the region formed as a result of removal of the first semiconductor layers 106. Since the filling layer 135 is a semiconductor material, the dielectric properties of the oxide layers 129a, 129b, 129c will prevent the filling layer 135 from growing on the oxide layers 129a, 129b, 129c.

It has been observed that the ability for effective removal of the first semiconductor layers 106 (e.g., SiGe) and formation of the filling layer 135 (e.g., Ge) are closely related to the porosity of the oxide layer 129a. Therefore, the Ge concentration in the first semiconductor layers 106 should be carefully controlled so that the etching gas and the deposition gas can pass through the oxide layer 129a without affecting the integrity of the oxide layer 129a. If the Ge at. % is not high enough (e.g., less than about 30 at. %), the porosity of the oxide layer 129a may not be sufficient for easy passage of the chemical gas through the oxide layer 129a, resulting in ineffective removal of the first semiconductor layers 106 (e.g., SiGe) and defective formation of the filling layer 135 (e.g., Ge). On the other hand, if the Ge at. % is too high (e.g., greater than about 80 at. %), the porosity in the oxide layer 129a may be overwhelming and diminish the mechanical strength of the oxide layer 129a. As a result, the integrity of the oxide layer 129a is impaired during removal of the first semiconductor layers 106 and/or formation of the filling layer 135.

Likewise, if the Ge at. % of the etch stop layer 111 is too high (e.g., greater than about 35 at. %), there may be no selectivity between SiGe (e.g., the first semiconductor layers 106) and the etch stop layer 111 when forming the filling layers 135. On the other hand, if the Ge at. % of the etch stop layer 111 is too less (e.g., less than about 10 at. %), there may be no selectivity between SiGe (e.g., the etch stop layer 111) and Si (e.g., the second semiconductor layers 108).

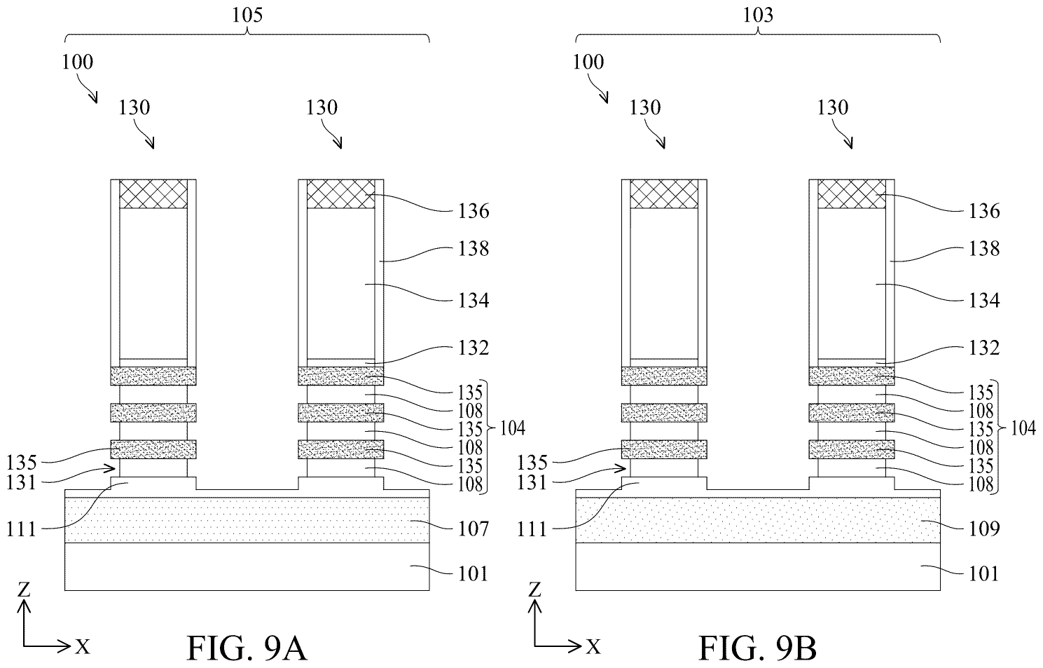

In FIGS. 9A and 9B, edge portions of each second semiconductor layer 108 of the stack of semiconductor layers 104 are removed horizontally along the X direction. During the removal of the second semiconductor layers 108, the oxide layers 129a, 129b, 129c are also removed. In some embodiments, a single prolonged etch process may be performed to remove both the oxide layers 129a, 129b, 129c and the second semiconductor layers 108. Alternatively, a first etch process may be performed to remove the oxide layers 129a, 129b, 129c, and a second etch process may be performed to remove a portion of the second semiconductor layers 108. In either case, the etch process is selective so that the filling layer 135 is not substantially etched. The removal of the edge portions of the second semiconductor layers 108 forms cavities 131.

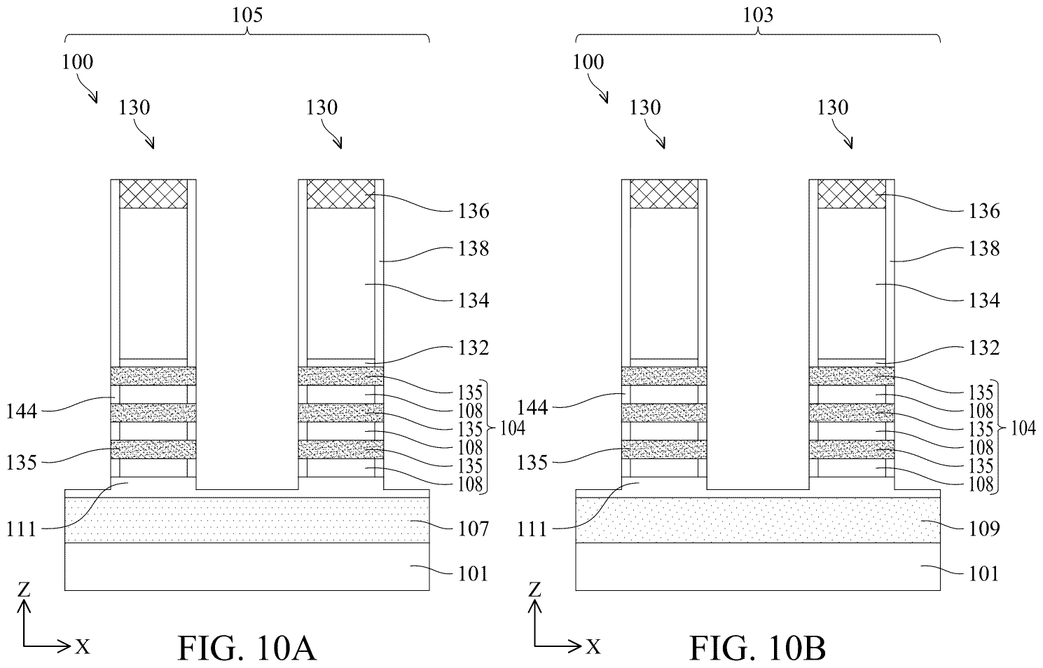

In FIGS. 10A and 10B, the cavities 131 (FIGS. 9A and 9B) are filled with a dielectric spacer 144. The inner spacers 144 may be formed by conformally forming a dielectric layer on the exposed surfaces of the sacrificial gate structures 130, the filling layers 135, the second semiconductor layers 108, and the etch stop layer 111, followed by an anisotropic etching process to remove portions of the dielectric layer. The dielectric layer may be made of a dielectric material. Suitable materials for the dielectric layer 144a may include, but are not limited to, SiO₂, Si₃N₄, SiC, SiCP, SiON, SiOC, SiCN, SiOCN, and/or other suitable material. Other materials, such as low-k materials with a k value less than about 3.5, may also be used. The formation of the dielectric layer may be formed by a conformal deposition process, such as ALD. The etching process may use an etchant that selectively removes the dielectric layer without substantially removing the gate spacers 138, the filling layer 135, the second semiconductor layers 108, and the etch stop layer 111. The dielectric layer within the cavities 131 are protected by the filling layers 135 during the anisotropic etching process. The remaining second semiconductor layers 108 are capped between the inner spacers 144 along the X direction.

In FIGS. 11A and 11B, epitaxial S/D features 146, 147 are formed in the source/drain (S/D) regions at the first and second device regions 103, 105. The epitaxial S/D features 146, 147 may be made of one or more layers of Si, SiP, SiC, SiAs, and SiCP for n-channel FETs or Si, SiGe, Ge for p-channel FETs. For p-channel FETs, p-type dopants, such as boron (B), may also be included in the epitaxial S/D features 146. For n-channel FETs, n-type dopants, such as phosphorus (P) or arsenic (As), may also be included in the epitaxial S/D features 147. The epitaxial S/D features 146, 147 may be formed by an epitaxial growth method using CVD, ALD or MBE. In some embodiments, the epitaxial S/D feature 146 for PMOS devices is a boron-doped silicon (Si:B), a boron-doped germanium (Ge:B), or a boron-doped silicon germanium (SiGe:B). In one exemplary embodiment, the epitaxial S/D features 146 is a boron-rich silicon germanium (SiGeB) having a concentration of boron in a range of about 1E20 atoms/cm³ to about 5E21 atoms/cm³, wherein the Ge concentration is about 15 at. % to about 80 at. %.

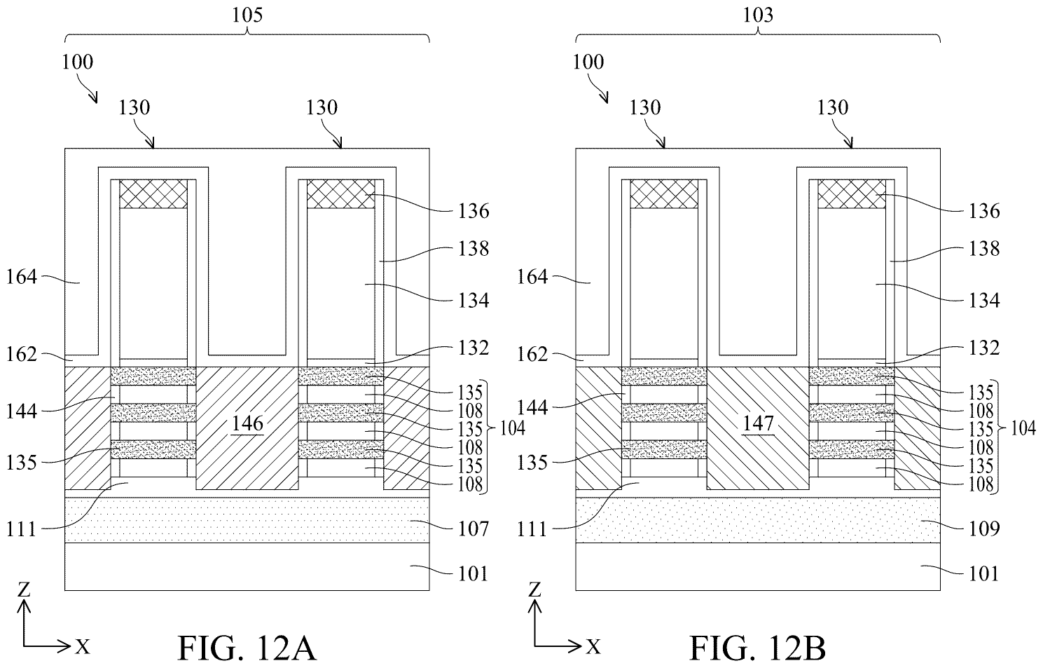

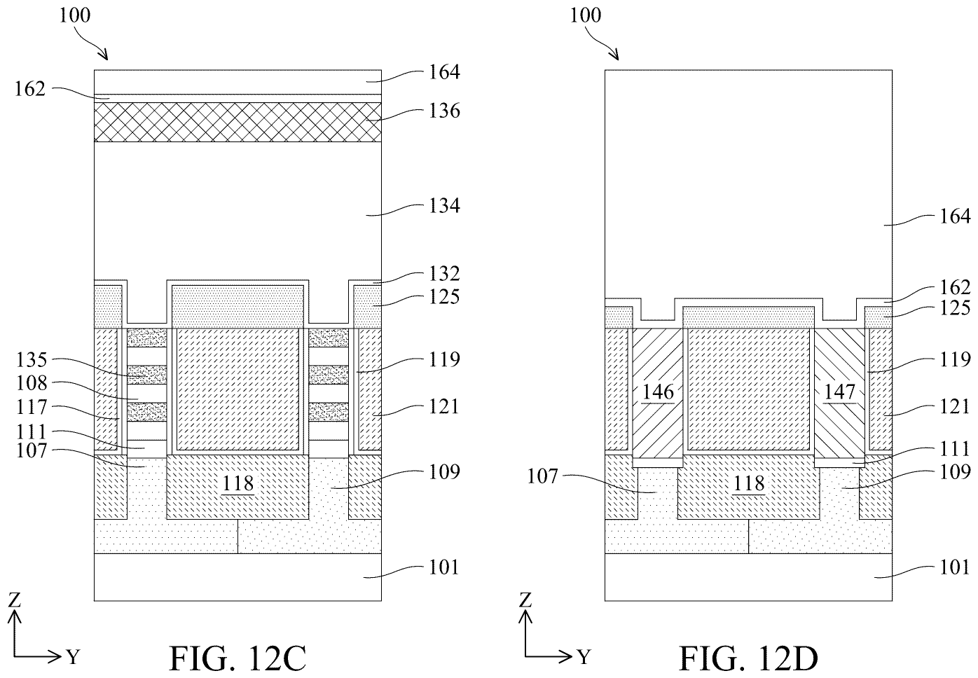

In FIGS. 12A-12D, after formation of the S/D features 146, 147, a contact etch stop layer (CESL) 162 is conformally formed on the exposed surfaces of the semiconductor device structure 100. The CESL 162 covers the S/D features 146, 147, the gate spacers 138, and the dielectric material 125 at the first and second device regions 103, 105. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include oxide formed with tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The ILD layer 164 may be deposited by a PECVD process or other suitable deposition technique.

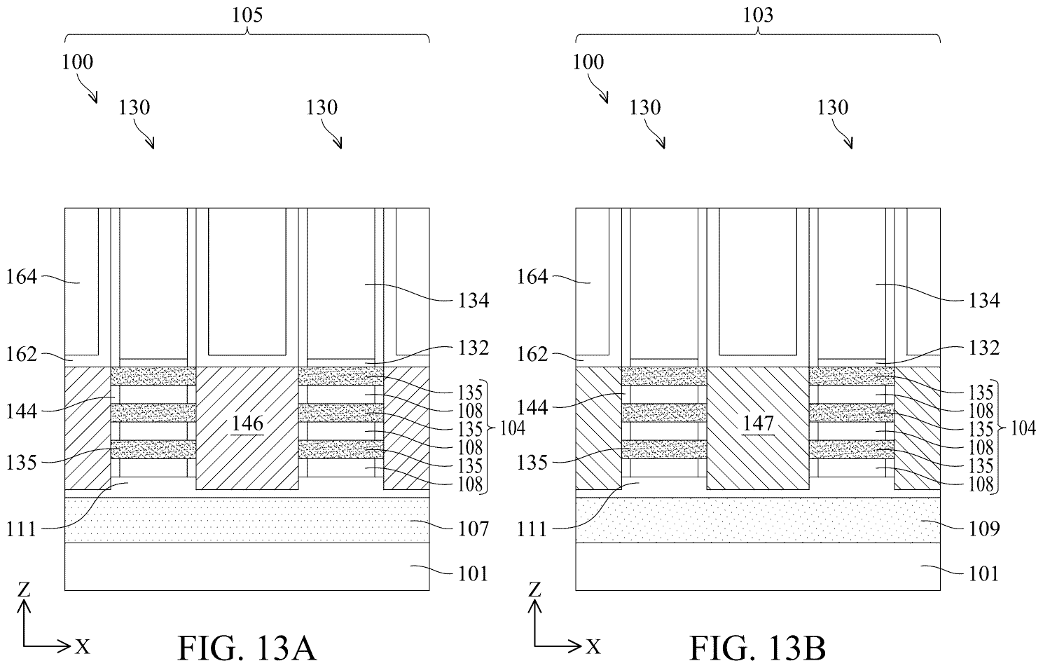

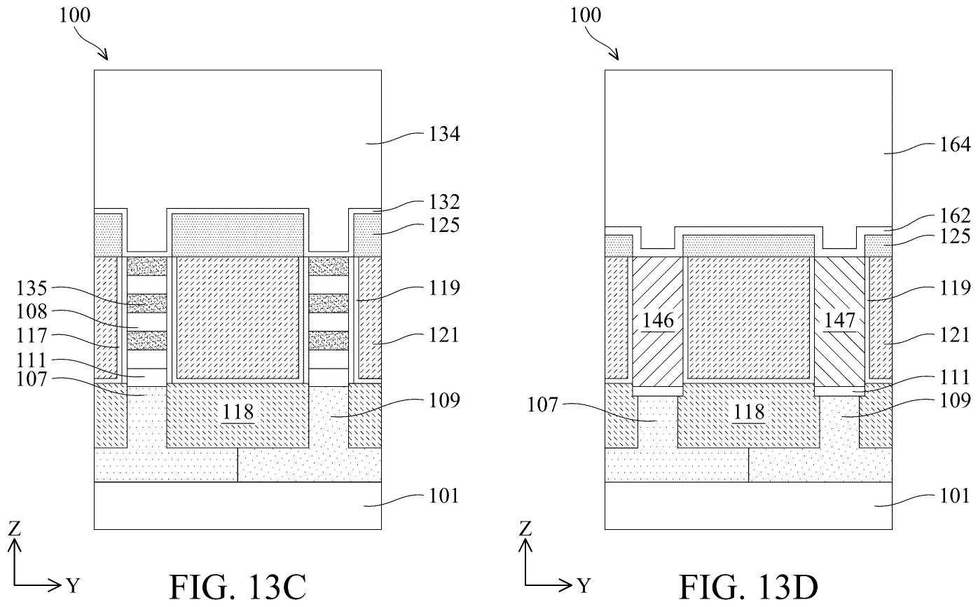

In FIGS. 13A-13D, after the ILD layer 164 has been formed, a planarization operation, such as CMP, is performed on the semiconductor device structure 100 to remove portions of the ILD layer 164, the CESL 162, and the mask layer 136 until the sacrificial gate electrode layer 134 is exposed.

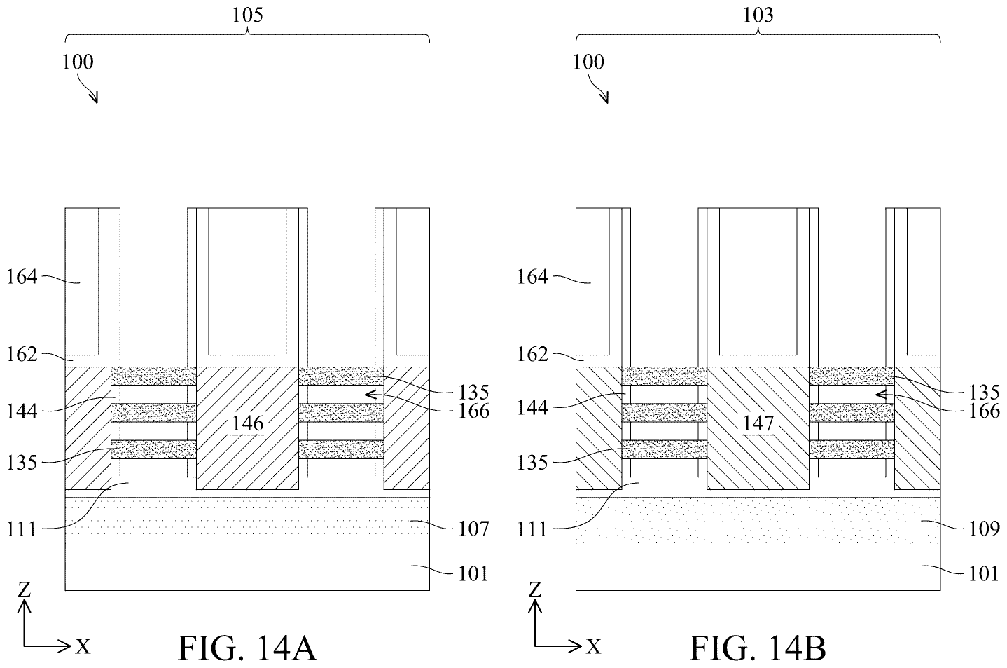

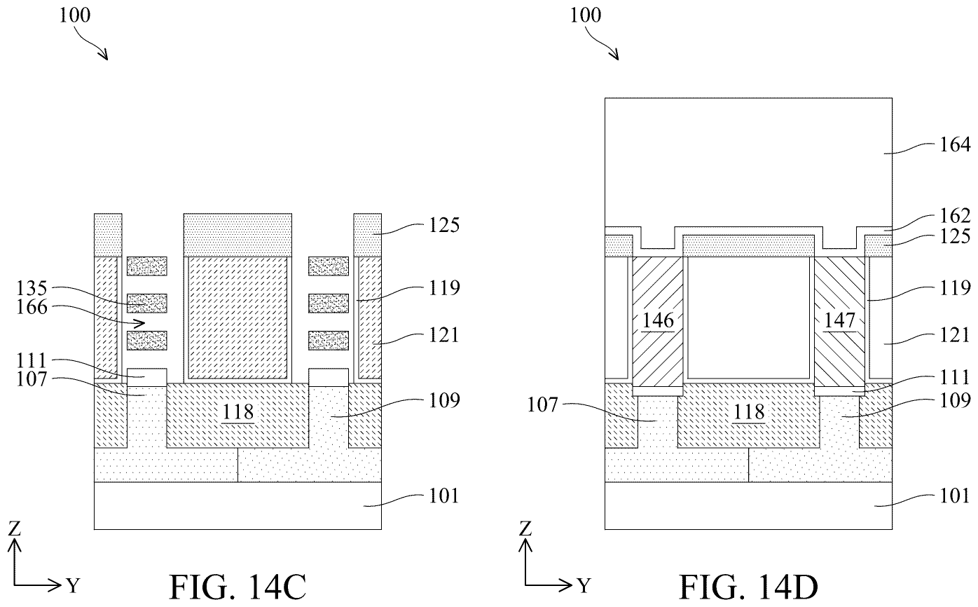

In FIGS. 14A-14D, the sacrificial gate structure 130, the cladding layer 117, and the second semiconductor layers 108 are removed from the semiconductor device structure 100 at the first and second device regions 103, 105. The removal of the sacrificial gate structure 130 and the second semiconductor layers 108 forms an opening 166 between gate spacers 138 and between the filling layers 135. The ILD layer 164 protects the S/D epitaxial features 146, 147 during the removal processes. Since the bottommost second semiconductor layers 108 and the substrate 101 are formed from the same material (e.g., silicon), the use of the etch stop layer 111 creates an etch selectivity with respect to the substrate 101 and thus prevents etchants from over-etching the top portion of the substrate 101, which may otherwise form an excessive size of the gate electrode layer if no etch stop layer 111 were provided.

The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. After the removal of the sacrificial gate structure 130, the cladding layers 117 and the second semiconductor layers 108 are exposed. The removal of the cladding layers 117 and the second semiconductor layers 108 exposes the filling layers 135. The removal process may be any suitable etch processes, such as dry etch, wet etch, or a combination thereof. The etch process may use an etchant that selectively removes the cladding layers 117 and the second semiconductor layers 108 without substantially removing the gate spacers 138, the ILD layer 164, the CESL 162, the dielectric material 125, and the filling layers 135. Upon removal of the sacrificial gate structure 130 and the second semiconductor layers 108, a portion of the filling layers 135 is exposed in the opening 166.

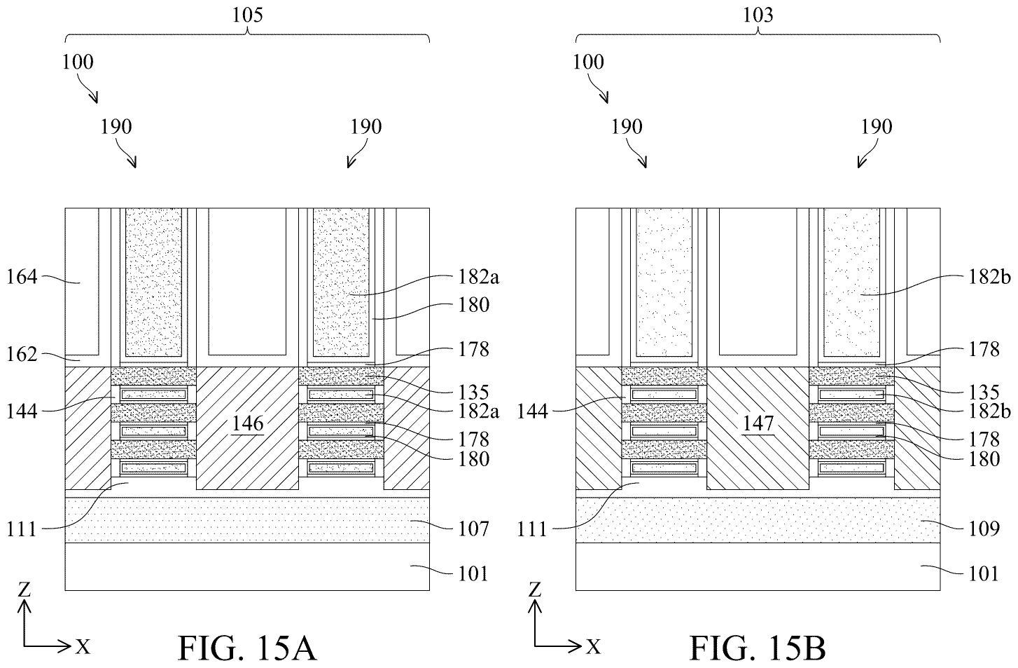

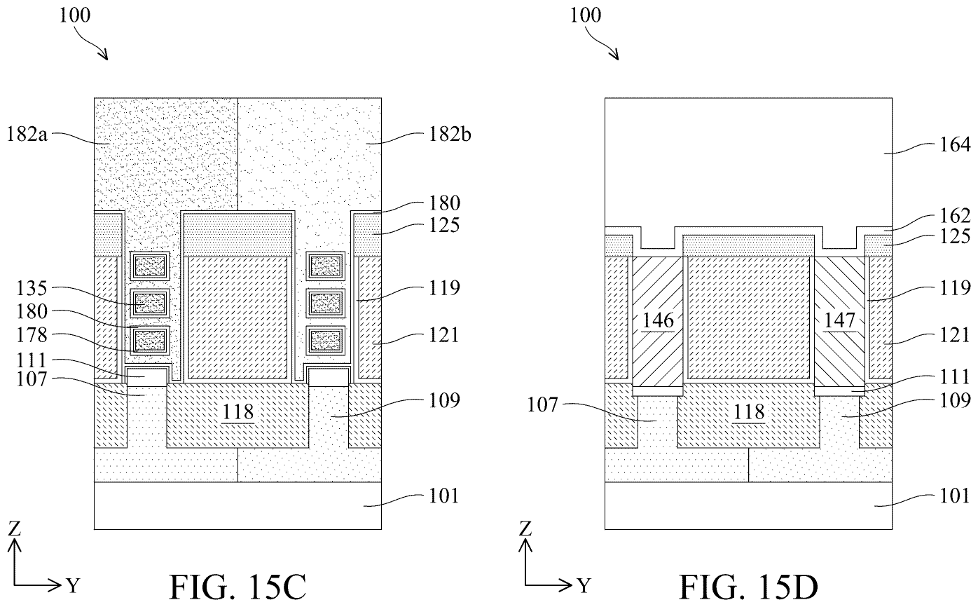

In FIGS. 15A-15D, replacement gate structures 190 are formed in the region provided by removal of the cladding layers 117 and the second semiconductor layers 108 at the first and second device regions 103, 105. The replacement gate structures 190 each includes an interfacial layer (IL) 178, a gate dielectric layer 180, and a gate electrode layer 182a/182b. The interfacial layer (IL) 178 is formed to surround exposed surfaces of the first semiconductor layers 106. The IL 178 may also form on the exposed etch stop layer 111. The IL 178 may include or be made of an oxygen-containing material or a silicon-containing material, such as silicon oxide, silicon oxynitride, oxynitride, hafnium silicate, etc. In one embodiment, the IL 178 is silicon oxide. The IL 178 may be formed by CVD, ALD, a clean process, or any suitable process. Next, the gate dielectric layer 180 is formed on the exposed surfaces of the semiconductor device structure 100. In some embodiments, the gate dielectric layer 180 is formed to wrap around and in contact with the IL 178. The gate dielectric layer 180 also forms on and in contact with the liner 119 and the dielectric material 125 (FIGS. 15C and 15D). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (Al₂O₃), aluminum silicon oxide (AlSiO), zirconium oxide (ZrO), titanium oxide (TiO), tantalum oxide (Ta₂O₅), yttrium oxide (Y₂O₃), silicon oxynitride (SiON), oxide with nitrogen doped dielectrics combined with metal content high-k dielectric (having a k value >13), or other suitable dielectrics having a k value ≥9. The gate dielectric layer 180 may be a conformal layer formed by a conformal process, such as an ALD process or a CVD process.

After formation of the IL 178 and the gate dielectric layer 180, the gate electrode layer 182a/182b is formed over the gate dielectric layer 180. The gate electrode layer 182a may be formed to fill the openings 166 (FIGS. 14A and 14B) and fully surround a portion of each of the first semiconductor layers 106 at the second device region 105. The gate electrode layer 182b may be formed to fill the openings 166 and fully surround a portion of each of the first semiconductor layers 106 at the first device region 103. In some embodiments, the gate electrode layers 182a, 182b may be formed using multiple layers, each layer deposited sequentially adjacent to each other using a highly conformal deposition process such as ALD. Other deposition technique such as PVD, CVD, or electro-plating may also be used. While not shown, the gate electrode layer 182a may include a capping layer, a barrier layer, an n-metal work function layer, a p-metal work function layer, and a fill material. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The n-metal work function layer may be formed from a metallic material such as W, Cu, AlCu, TiAlC, TiAlN, Ti, TiN, Ta, TaN, Co, Ni, Ag, Al, TaAl, TaAlC, TaC, TaCN, TaSiN, Mn, Zr, other suitable N-type work function materials, or combinations thereof. The p-metal work function layer may be formed from a metallic material such as W, Al, Cu, TiN, Ti, Ti AlN, Ta, TaN, Co. Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Once the n-metal work function layer and the p-metal work function layer are formed, the fill material is deposited to fill a remainder of the opening 166. The fill material may be a material such as W, Al, Cu, AlCu, W, Ti, TiAlN, TaC, TaCN, TaSiN, Mn, Zr, TiN, Ta, TaN, Co, Ni, combinations of these, or the like.

Similarly, the gate electrode layer 182b may be formed using multiple layers and materials similar to the gate electrode layer 182a discussed above. In some embodiments, one or more of the layers within the gate electrode layer 182a and the gate electrode layer 182b may be formed during a same series of steps. For example, the capping layers and the barrier layers in both of the gate electrode layer 182a and the gate electrode layer 182b may be formed simultaneously, while other layers such as the n-metal work function layer and the p-metal work function layer may be formed and/or patterned independently of each other. Any suitable combination of depositions and removals may be utilized to form the gate electrode layer 182a and the gate electrode layer 182b.

Once the openings 166 have been filled, the materials of the gate electrode layer 182a and the gate electrode layer 182b may be planarized by a planarization process (e.g., CMP) to remove any material that is outside of the openings left behind by the removal of the sacrificial gate electrode layer 134.

In FIGS. 16A-16D, the gate electrode layer 182a, 182b may be subject to one or more metal gate etching back (MGEB) processes. The MGEB processes are performed so that the top surfaces of the gate electrode layer 182a, 182b and the gate dielectric layer 180 are recessed to a level below the top surface of the gate spacers 138. In some embodiments, the gate spacers 138 are also recessed to a level below the top surface of the ILD layer 164. A self-aligned contact layer 173 is formed over the gate electrode layer 182a, 182b and the gate dielectric layer 180 between the gate spacers 138. The self-aligned contact layer 173 may be a dielectric material having an etch selectivity relative to the ILD layer 164. In some embodiments, the self-aligned contact layer 173 may be a dielectric material such as silicon nitride or a high-k dielectric layer. Once formed, the self-aligned contact layer 173 may be planarized using a planarization process such as a CMP.

After formation of the self-aligned contact layer 173, contact openings are formed through the ILD layer 164 and the CESL 162 to expose the epitaxial S/D feature 146, 147. A silicide layer 184 is then formed on the S/D epitaxial feature 146, 147, and a S/D contact 186 is formed in the contact opening on the silicide layer 184. The contact 186 may include an electrically conductive material, such as Al, Cu, W, Co, Ti, Ta, Ru, TiN, TiAl, TiAlN, TaN, TaC, NiSi, CoSi, combinations of these, or the like. The silicidation may be performed by blanket deposition of an appropriate metal layer, followed by an annealing step which causes the metal to react with the underlying exposed silicon. Un-reacted metal is then removed, such as with a selective etch process. The contact 186 may be formed in the contact openings using sputtering, CVD, electroplating, electroless plating, or the like, to fill and/or overfill the contact openings. Any deposited material outside of the contact openings may be removed using a planarization process, such as a CMP.

The semiconductor device structure 100 may then undergo further complementary metal oxide semiconductor (CMOS) and/or back-end-of-line (BEOL) processes to form various features such as transistors, contacts/vias, interconnect metal layers, dielectric layers, passivation layers, etc. FIG. 16D illustrates an enlarged view of a portion of the semiconductor device structure 100 shown in FIGS. 16A and 16B, in accordance with some alternative embodiments. While the etch stop layer 111 is shown to have a substantially flat top surface in various figures of the present disclosure, it is contemplated that the etch stop layer 111 may be etched to have a curved profile (e.g., concave) during removal of the portions of the fin structures 112 (FIGS. 6A-6D). The etch stop layer 111 with such a curved profile is applicable to other embodiments of the present disclosure. As a result, the epitaxial S/D features 146, 147 are formed with a curved bottom surface 146b/147b.

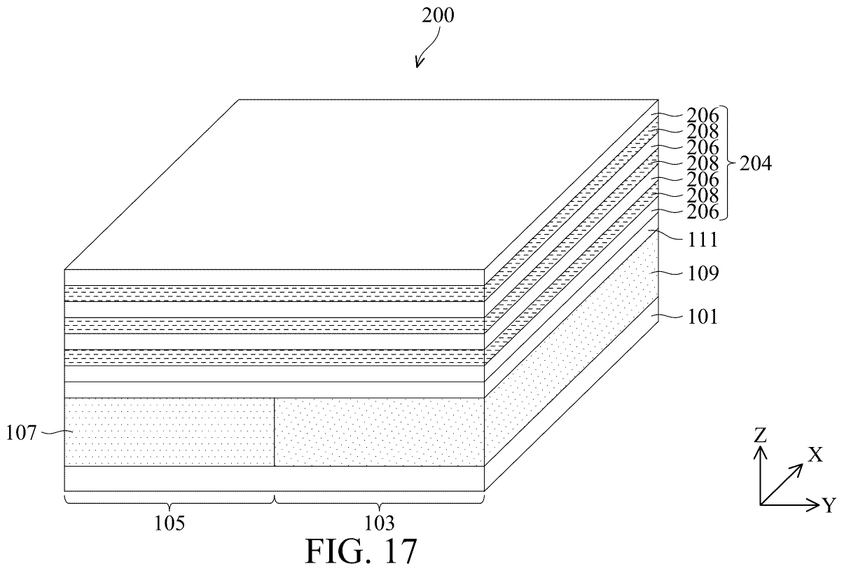

FIGS. 17-24D show exemplary processes for manufacturing a semiconductor device structure 200 according to another embodiment of the present disclosure. The embodiment of FIGS. 17-24D is similar to the embodiment shown in FIGS. 1-16D except that the stack of the semiconductor layers 204 includes 4 layers of first semiconductor layers 206 and 3 layers of second semiconductor layers 208 alternatingly arranged over the etch stop layer 111. The first semiconductor layers 106 and the second semiconductor layers 108 are made of semiconductor materials having different etch selectivity and/or oxidation rates. For example, the first semiconductor layers 206 may be made of Si and the second semiconductor layers 208 may be made of SiGe. In some embodiments, the first semiconductor layers 206 may be made of SiGe having a Ge concentration of about 30 at. % or above, such as about 35 at. % to about 80 at. %.

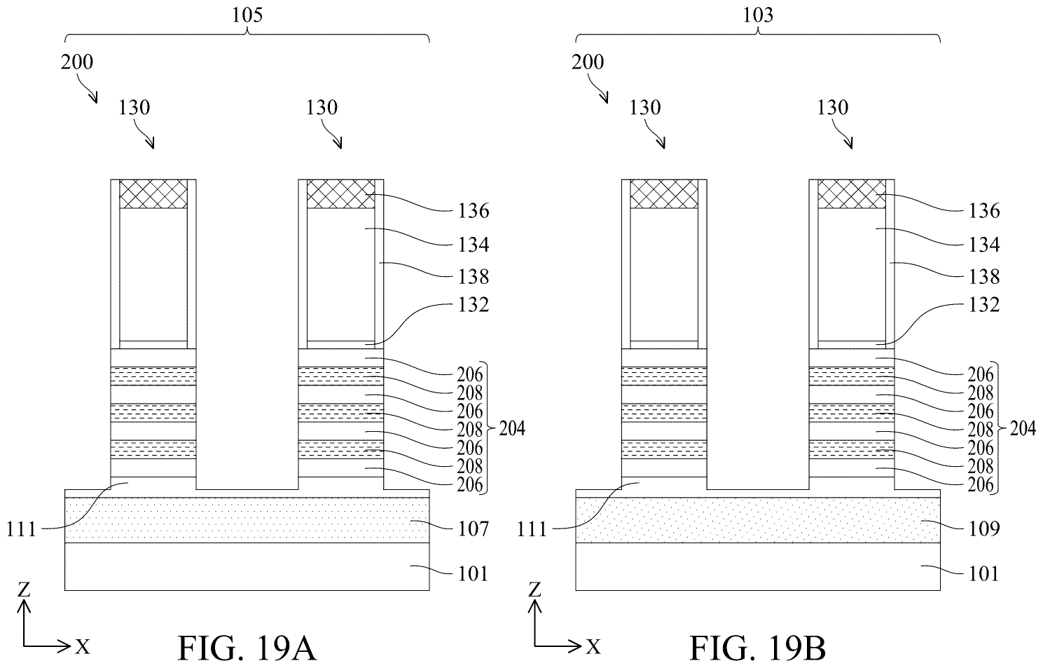

In FIGS. 19A and 19B, exposed portions of the stack of the semiconductor layers 204, the cladding layers 117, and the dielectric material 125 at the first and second device regions 103, 105 not covered by the sacrificial gate structures 130 and the gate spacers 138 are recessed to form source/drain (S/D) regions. The removal process may include one or more suitable etch processes, and may be performed so that the sidewalls of the bottommost second semiconductor layer 108 of the stack of the semiconductor layers 204 are fully exposed and a sidewall of the etch stop layer 111 is exposed.

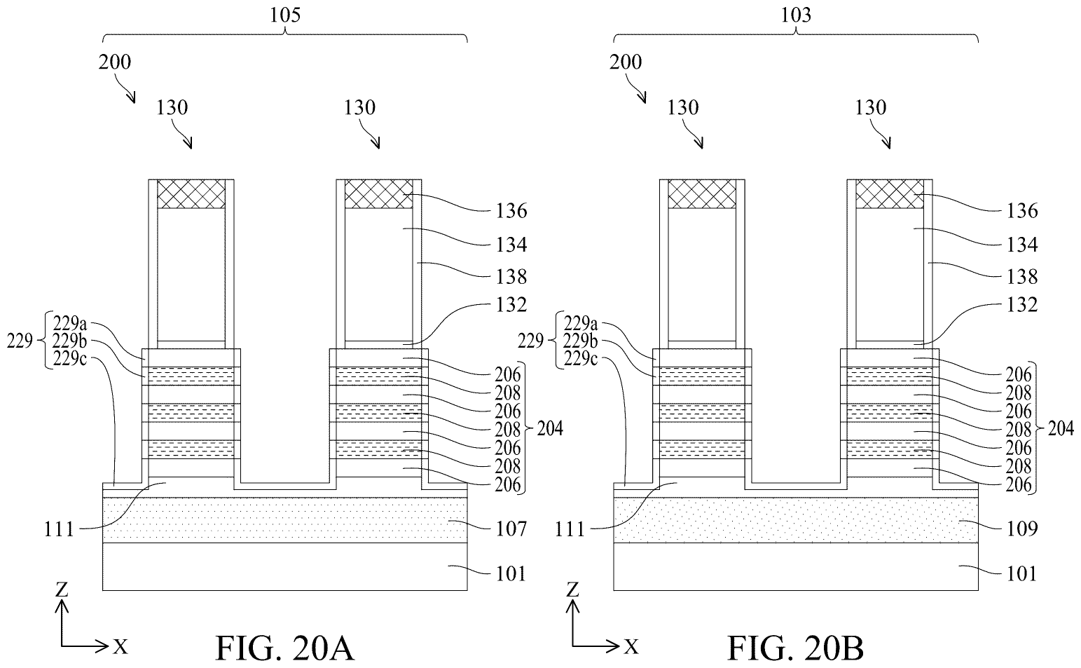

In FIGS. 20A and 20B, oxide layers 229a, 229b, 229c (collectively referred to as oxide layer 229) are formed on the exposed surfaces of the first semiconductor layers 206, the second semiconductor layers 208, and the etch stop layer 111, respectively. The oxide layers 229a, 229b, 229c may be formed as a result of a cleaning process and a post-treatment process, in a similar manner as the oxide layers 129a, 129b, 129c discussed above with respect to FIGS. 7A and 7B. In cases where the first semiconductor layers 206 include Si, the second semiconductor layers 208 include SiGe having higher atomic concentration of Ge (e.g., about 35 at. % or greater), and the etch stop layer 111 includes SiGe having lower atomic concentration of Ge (e.g., about 30 at. % or lower), the oxide layer 229b formed on the surface of the second semiconductor layers 208 may include silicon germanium oxide (SiGeO) with a greater amount of Ge, and the oxide layer 229a formed on the surface of the first semiconductor layers 206 may include silicon oxide (SiO), and the oxide layer 229c formed on the surface of the etch stop layer 111 may include SiGeO with a lesser amount of Ge, respectively. The post-treatment process may be any suitable etch process that selectively removes Ge from SiGeO. The removal of germanium from the oxide layers 229b and 229c results in oxide layers 229a, 229b, 229c with different film qualities. For example, the oxide layer 229b may become a porous SiO as compared to the oxide layer 229a, and the oxide layer 229c may become a slightly porous SiO as compared to the oxide layer 229a. As discussed previously, the greater porosity of the oxide layer 229b allows easy replacement of SiGe with Ge at a later stage.

The oxide layer 229 may have a thickness in a range between about 5 Å and about 10 Å. If the thickness of the oxide layer 229 is below about 5 Å, the oxide layer 129 may not be thick enough to function as its intended purpose. If the thickness of the oxide layer 229 is greater than about 10 Å, the chemical gas may have trouble passing through.

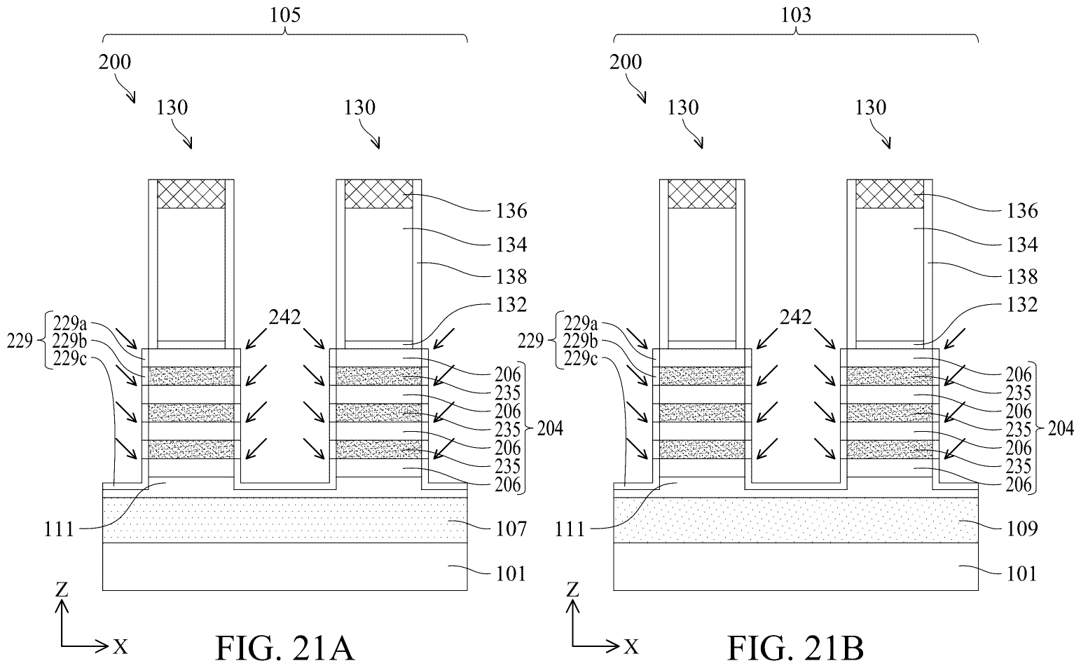

In FIGS. 21A and 21B, the second semiconductor layers 208 are removed, and a filling layer 235, such as the filling layer 235, is refilled in the region where the second semiconductor layers 208 were removed. The filling layer 235 functions as a channel layer for PMOS and NMOS devices, and may be made of a semiconductor material. In one embodiment, the filling layer 235 is formed of germanium (e.g., pure Ge). Due to lattice mismatch between germanium and silicon, using germanium as a material for the filling layer 235 will produce strain (i.e., strained germanium) and thus enhance channel mobility for transistor devices, particularly the PMOS devices (e.g., P-type gate all around transistors). Likewise, while germanium is discussed, other semiconductor materials having an atomic radius greater (e.g., about 0.5 times to about 1.5 times greater) than the atomic radius of the chemical element used for the first semiconductor layers 206 (e.g., silicon), may also be used. The filling layer 235 may be formed in a similar manner as the filling layer 135 as discussed above with respect to FIGS. 8A and 8B. Since the oxide layer 229b is porous, the etching gas can easily flow through the oxide layer 229b and remove the second semiconductor layers 208 without removing the oxide layer 229b. Thereafter, the semiconductor device structure 200 is exposed to a deposition gas 242 to epitaxially grow the filling layer 235 in the region formed as a result of removal of the second semiconductor layers 208. Likewise, the Ge concentration in the second semiconductor layers 208 should be carefully controlled (e.g., about 35 at. % to about 80 at. %) so that chemical gas can pass through the oxide layer 229b without affecting the integrity of the oxide layer 229b.

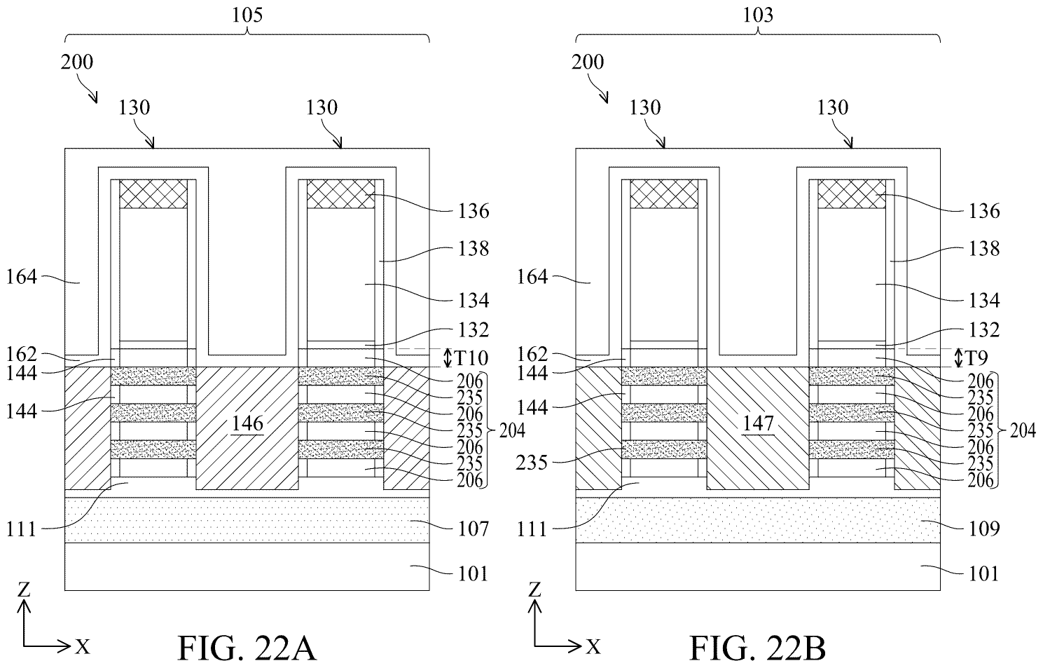

In FIGS. 22A and 22B, the oxide layers 229a, 229b, 229c are removed, and edge portions of each first semiconductor layer 206 of the stack of semiconductor layers 204 are removed horizontally along the X direction. The etch process is selective so that the filling layer 235 is not substantially etched. The removal of the edge portions of the first semiconductor layers 206 forms cavities, which are then filled with a dielectric material to form inner spacers 144. Thereafter, epitaxial S/D features 146, 147 are formed in the source/drain (S/D) regions at the first and second device regions 103, 105. The epitaxial S/D features 146, 147 may grow laterally from the sidewalls of the filling layers 235 and form facets corresponding to crystal planes of the material of the filling layers 235. In some embodiments, the top surface of the epitaxial S/D features 146, 147 is at substantially the same height as the top surface of the topmost filling layer 235. A contact etch stop layer (CESL) 162 and an interlayer dielectric (ILD) layer 164 are sequentially formed over the semiconductor device structure 200, in a similar fashion as discussed above with respect to FIGS. 9A-9B to 12A-12B.

In some embodiments, the topmost dielectric spacer 144 at the first device region 103 may have a thickness T9 in a range of about 3 nm to about 8 nm, and the topmost dielectric spacer 144 at the second device region 105 may have a thickness T10 in a range of about 2 nm to about 9 nm. If the thickness T9 and thickness T10 of the topmost dielectric spacer 144 at the first and second device regions 103, 105 is greater than about 9 nm, the resistance may be increased. On the other hand, if the thickness T9 and thickness T10 of the topmost dielectric spacer 144 at the first and second device regions 103, 105 is less than about 2 nm, the gate-to-source/drain parasitic capacitance may be increased.

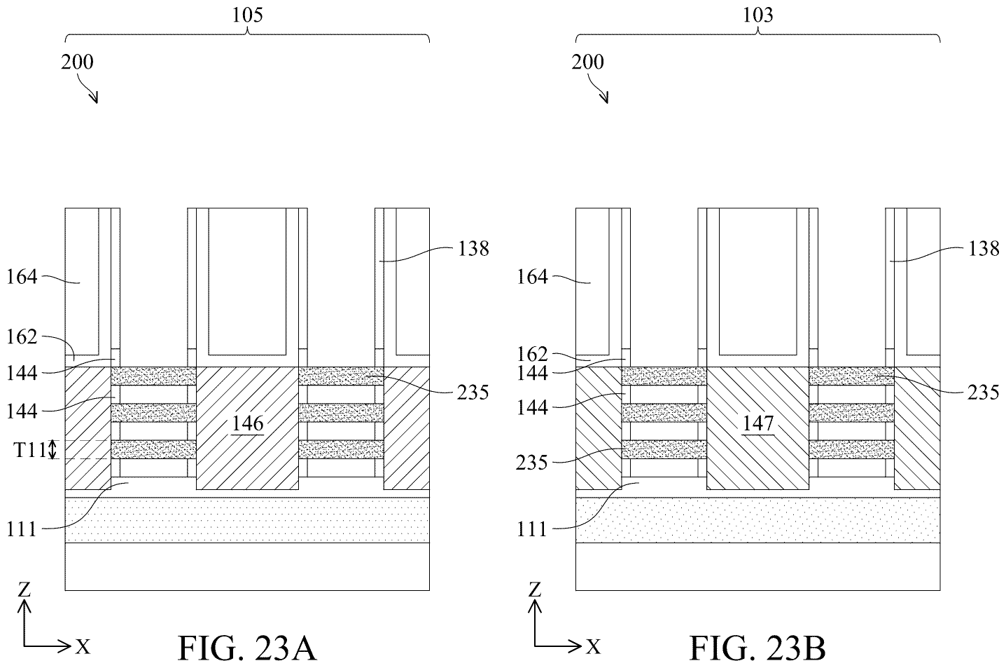

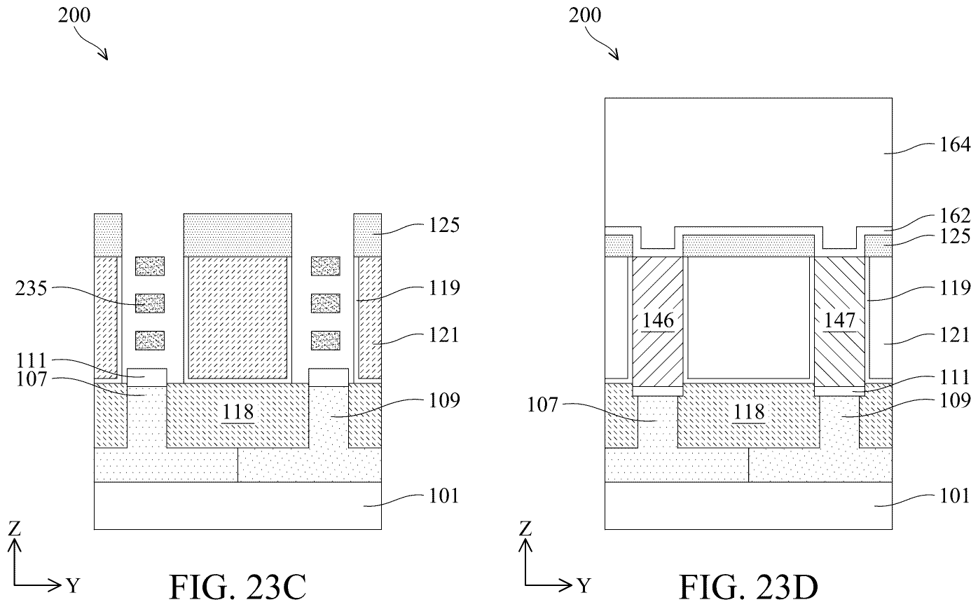

In FIGS. 23A-23D, after the ILD layer 164 has been formed, a planarization operation, such as CMP, is performed on the semiconductor device structure 200 to remove portions of the ILD layer 164, the CESL 162, and the mask layer 136 until the sacrificial gate electrode layer 134 is exposed. The sacrificial gate structure 130, the cladding layer 117, and the first semiconductor layers 206 are then removed from the semiconductor device structure 200 at the first and second device regions 103, 105. Upon removal of the sacrificial gate structure 130 and the first semiconductor layers 206, a portion of the filling layers 235 is exposed.

In some embodiments, the filling layers 235 may be consumed when removing the first semiconductor layers 206 for replacement gate structure. In such cases, each filling layer 235 at both the first and second device regions 103, 105 may have a thickness T11 that is less than the thickness T10 of the topmost dielectric spacer 144.

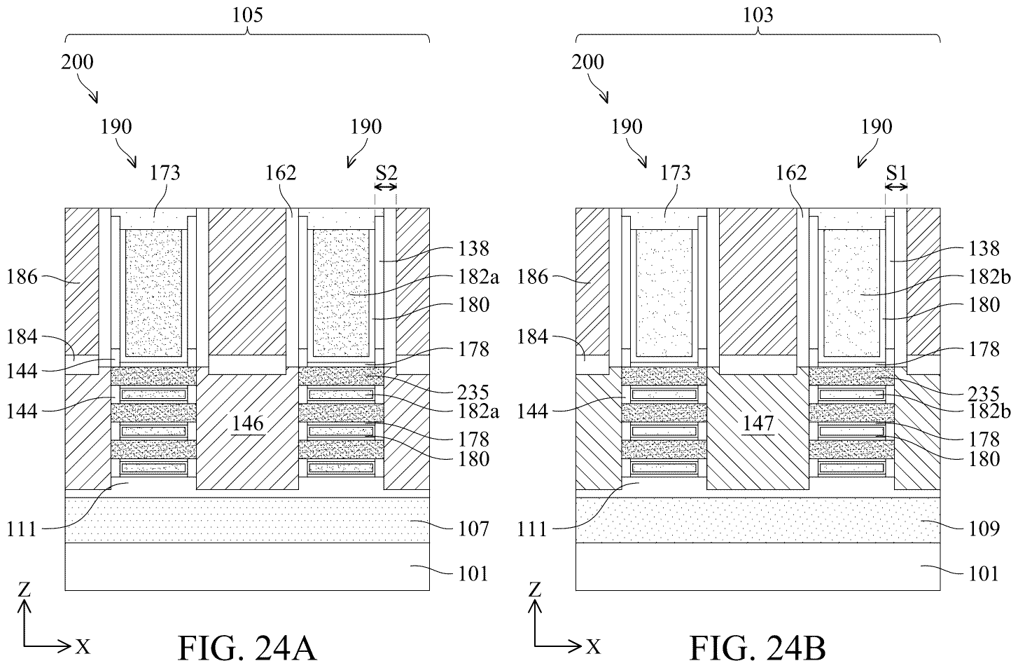

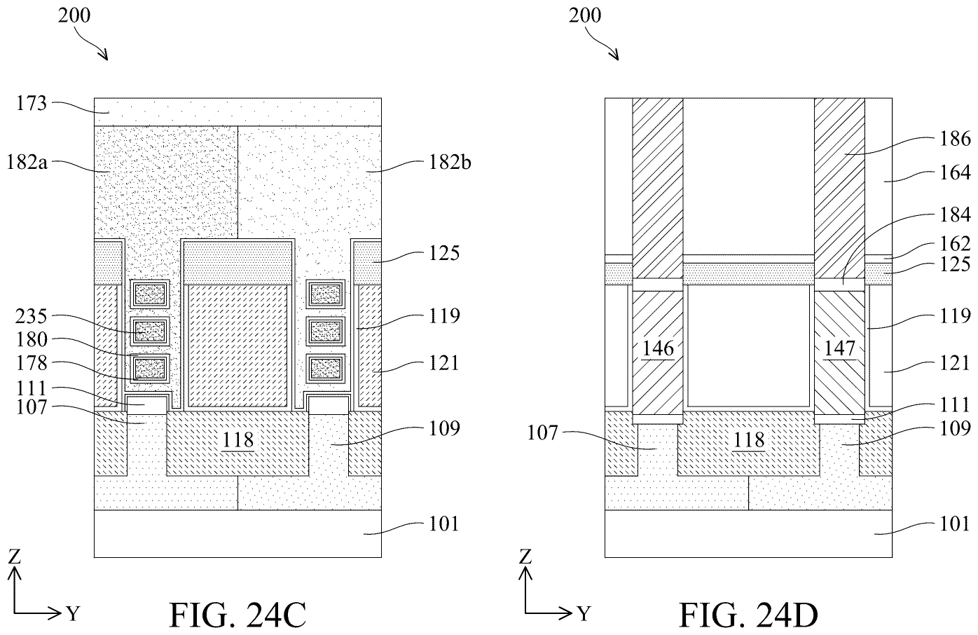

In FIGS. 24A-24D, replacement gate structures 190 are formed in the region provided by removal of the cladding layers 117 and the second semiconductor layers 108 at the first and second device regions 103, 105. The replacement gate structures 190 each includes an interfacial layer (IL) 178, a gate dielectric layer 180, and a gate electrode layer 182a/182b, and may be formed in a similar manner as discussed above with respect to FIGS. 15A-15D. Thereafter, the gate electrode layer 182a and the gate electrode layer 182b are planarized by a planarization process, and MGEB processes are performed so that the top surfaces of the gate electrode layer 182a, 182b and the gate dielectric layer 180 are recessed to a level below the top surface of the gate spacers 138. A self-aligned contact layer 173 is then formed over the gate electrode layer 182a, 182b and the gate dielectric layer 180 between the gate spacers 138.

After formation of the self-aligned contact layer 173, contact openings are formed through the ILD layer 164 and the CESL 162 to expose the epitaxial S/D feature 146, 147. A silicide layer 184 is then formed on the S/D epitaxial feature 146, 147, and a S/D contact 186 is formed in the contact opening on the silicide layer 184. Any deposited material outside of the contact openings may be removed using a planarization process, such as a CMP.

As can be seen in FIGS. 24A and 24B, the two opposing ends or edge portions of the topmost Ge channel layer (i.e., filling layer 235) at both first and second device regions 103, 105 are disposed between and in contact with inner spacers 144 in a symmetric manner. Since the first semiconductor layers 206 were previously removed, the topmost dielectric spacer 144 is now disposed between the gate electrode layer 182a/182b and the S/D contact 186. As such, the gate-to-source/drain parasitic capacitance of the NMOS and PMOS devices is minimized due to the increased dielectric body combining the topmost dielectric spacer 144 and the CESL 162 (represented by distance S1 and S2, respectively).

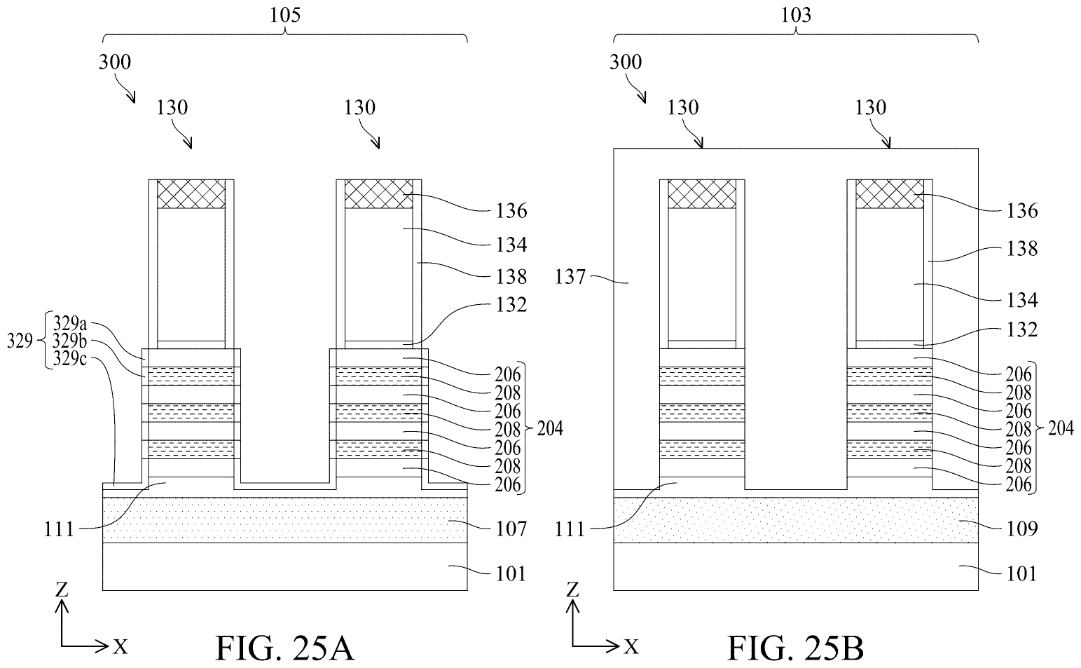

FIGS. 25A-25B to 32A-32D show exemplary processes for manufacturing a semiconductor device structure 300 according to yet another embodiment of the present disclosure. The embodiment of FIGS. 25A-25B to 32A-32D is similar to the embodiment shown in FIGS. 17-24D except that different number/material of channel layers are adapted by NMOS and PMOS devices at the first and second device regions 103, 105. FIGS. 25A and 25B illustrate a stage of the semiconductor device structure 300 after source/drain (S/D) regions are formed, such as the semiconductor device structure 200 shown in FIGS. 19A and 19B. After S/D regions are formed, a hard mask layer 137 is deposited on exposed surfaces of the semiconductor device structure 300 at the first and second device regions 103, 105. The hard mask layer 139 is to be patterned to subsequently processing areas for one type of devices, such as N-type devices in the first device region 103 or P-type devices at the second device region 105. In some embodiments, the hard mask layer 137 is an oxide, such as aluminum oxide (AlOₓ). Thereafter, a photolithography process is performed to pattern the hard mask layer 137 to expose processing areas for one type of devices, such as N-type device areas or P-type device areas. The first device area 103 remains protected by the hard mask layer 137. In one exemplary embodiment, the hard mask layer 137 at the second device region 105 is patterned to expose areas over the N-type well 107 where P-type devices are to be formed.

After the photolithography process, oxide layers 329a, 329b, 329c (collectively referred to as oxide layer 329) are formed on the exposed surfaces of the first semiconductor layers 206, the second semiconductor layers 208, and the etch stop layer 111, respectively. The oxide layers 329a, 329b, 329c may be formed as a result of a cleaning process and a post-treatment process, in a similar manner as the oxide layers 129a, 129b, 129c discussed above with respect to FIGS. 7A and 7B. In cases where the first semiconductor layers 206 include Si, the second semiconductor layers 208 include SiGe having higher atomic concentration of Ge (e.g., about 35 at. % or greater), and the etch stop layer 111 includes SiGe having lower atomic concentration of Ge (e.g., about 30 at. % or lower), the oxide layer 329b formed on the surface of the second semiconductor layers 208 may include silicon germanium oxide (SiGeO) with a greater amount of Ge, and the oxide layer 329a formed on the surface of the first semiconductor layers 206 may include silicon oxide (SiO), and the oxide layer 329c formed on the surface of the etch stop layer 111 may include SiGeO with a lesser amount of Ge, respectively. The post-treatment process may be any suitable etch process that selectively removes Ge from SiGeO. The removal of germanium from the oxide layers 329b and 329c results in oxide layers 329a, 329b, 329c with different film qualities. For example, the oxide layer 329b may become a porous SiO as compared to the oxide layer 329a, and the oxide layer 329c may become a slightly porous SiO as compared to the oxide layer 329a. As discussed previously, the greater porosity of the oxide layer 329b allows easy replacement of SiGe with Ge at a later stage.

In FIGS. 26A and 26B, the second semiconductor layers 208 are removed, and a filling layer 335, such as the filling layer 135, is refilled in the region where the second semiconductor layers 208 were removed. The filling layer 335 functions as a channel layer for PMOS devices at the second device region 105, and may be made of a semiconductor material. In one embodiment, the filling layer 335 is formed of germanium (e.g., pure Ge). Due to lattice mismatch between germanium and silicon, using germanium as a material for the filling layer 335 will produce strain (i.e., strained germanium) and thus enhance channel mobility for transistor devices, particularly the PMOS devices (e.g., P-type gate all around transistors). Likewise, while germanium is discussed, other semiconductor materials having an atomic radius greater (e.g., about 0.5 times to about 1.5 times greater) than the atomic radius of the chemical element used for the first semiconductor layers 206 (e.g., silicon), may also be used. The filling layer 335 may be formed in a similar manner as the filling layer 135 as discussed above with respect to FIGS. 8A and 8B. Since the oxide layer 329b is porous, the etching gas can easily flow through the oxide layer 329b and remove the second semiconductor layers 208 without removing the oxide layer 329b. Thereafter, the semiconductor device structure 300 is exposed to a deposition gas 342 to epitaxially grow the filling layer 335 in the region formed as a result of removal of the second semiconductor layers 208. Likewise, the Ge concentration in the second semiconductor layers 208 should be carefully controlled (e.g., about 35 at. % to about 80 at. %) so that chemical gas can pass through the oxide layer 329b without affecting the integrity of the oxide layer 329b.

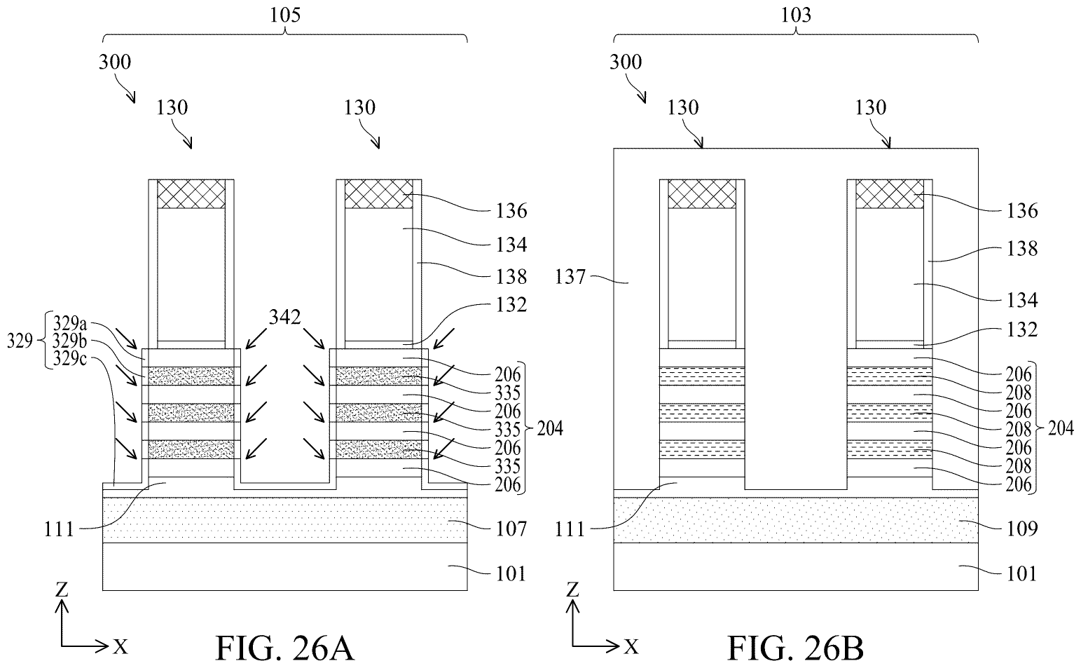

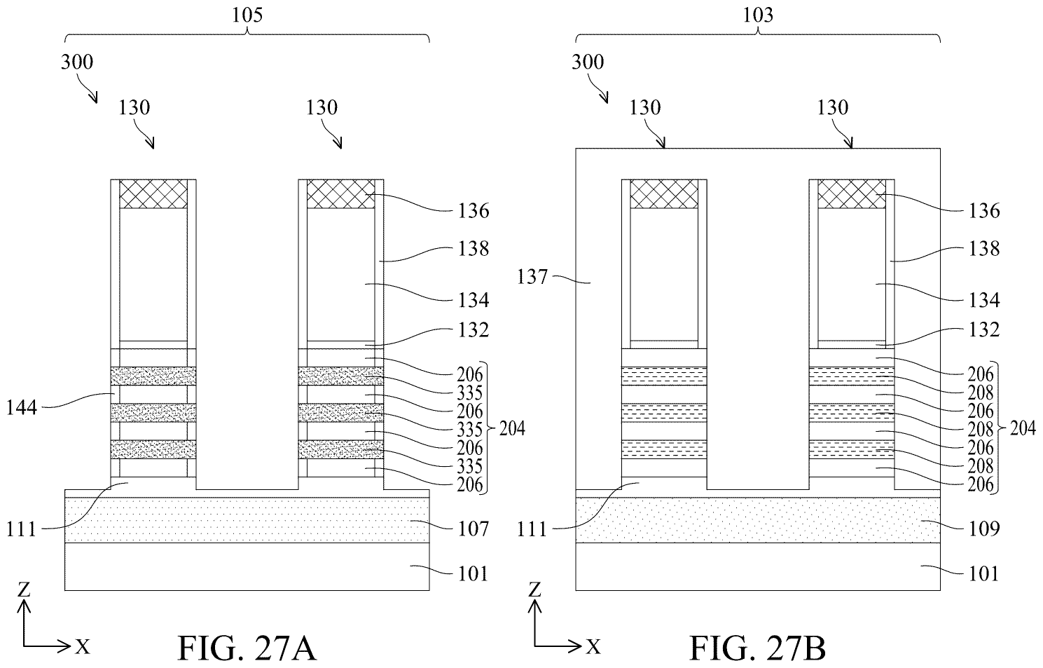

In FIGS. 27A and 27B, the oxide layers 329a, 329b, 329c are removed, and the edge portions of each first semiconductor layer 206 of the stack of semiconductor layers 204 at the second device region 105 are removed horizontally along the X direction. The etch process is selective so that the filling layer 335 is not substantially etched. The removal of the edge portions of the first semiconductor layers 206 forms cavities, which are then filled with a dielectric material to form inner spacers 144, in a similar fashion as discussed above with respect to FIGS. 22A and 22B.

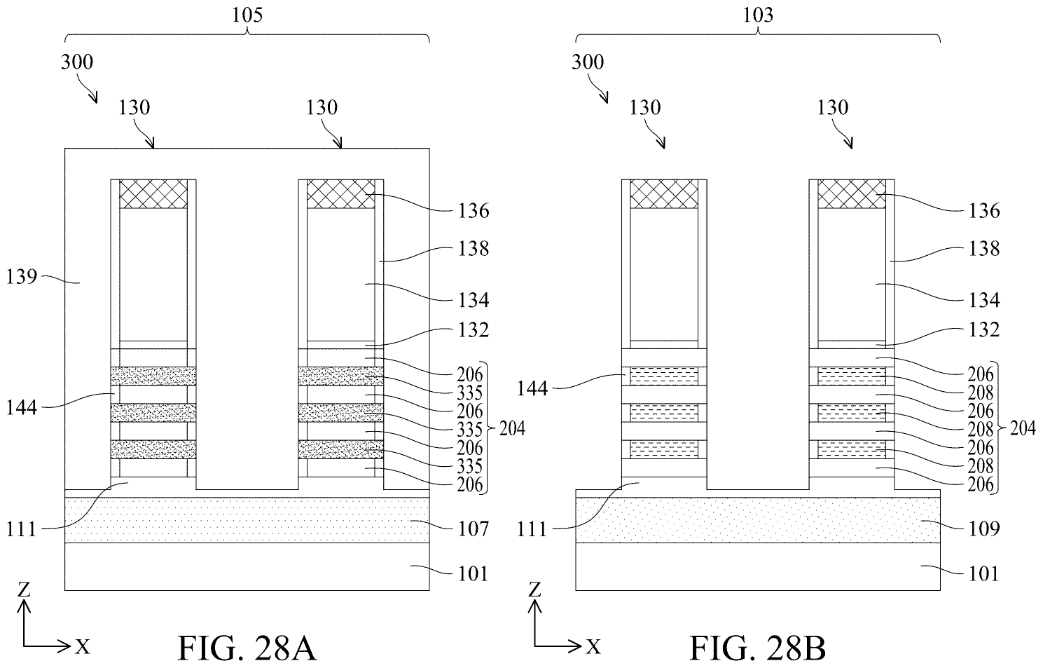

In FIGS. 28A and 28B, after the inner spacers 144 at the second device region 105 are formed, a hard mask layer 139, such as the hard mask layer 137, is deposited on exposed surfaces of the semiconductor device structure 300 at the second device region 105. Thereafter, a photolithography process is performed to pattern the hard mask layer 137 to expose processing areas at the first device region 103. Then, edge portions of each second semiconductor layer 208 of the stack of semiconductor layers 204 at the first device region 103 are removed horizontally along the X direction. The removal of the edge portions of the second semiconductor layers 208 forms cavities, which are then filled with a dielectric material to form inner spacers 144, in a similar fashion as discussed above with respect to FIGS. 22A and 22B.

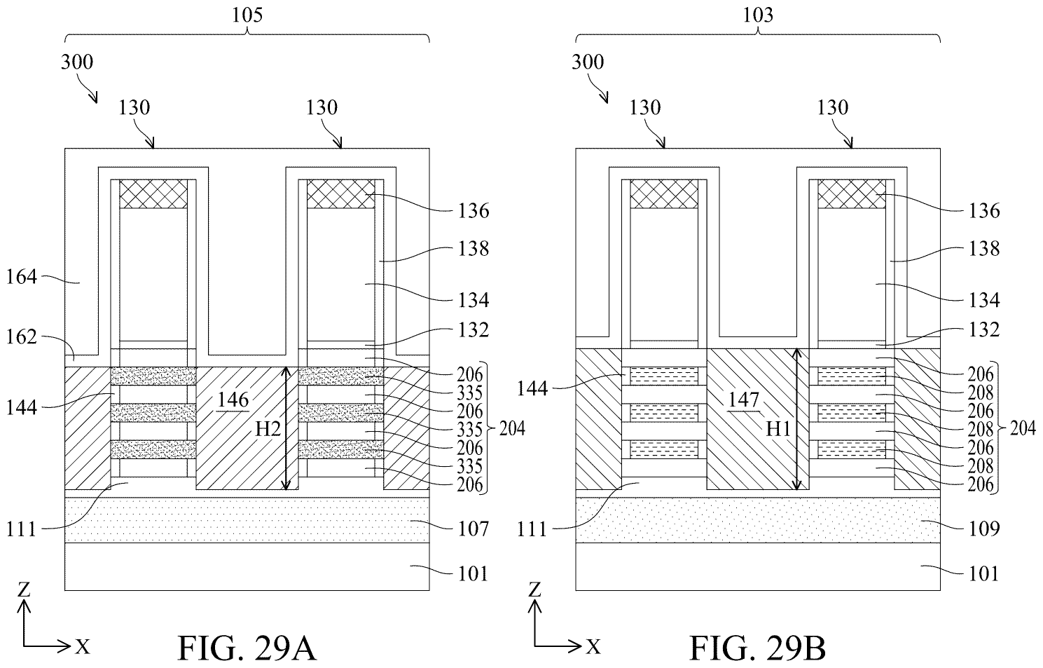

In FIGS. 29A and 29B, epitaxial S/D features 146, 147 are formed in the source/drain (S/D) regions at the first and second device regions 103, 105. The epitaxial S/D features 146, 147 may grow laterally from the filling layers 335 and the first semiconductor layers 206, respectively. The epitaxial S/D features 146, 147 may form facets corresponding to crystal planes of the material of the filling layers 335 and the first semiconductor layers 206. Due to different growth rates on different materials and the fact that the first semiconductor layers 206 at the first device region 103 and the filling layers 335 at the second device region 105 are arranged at different heights (owning to the patterning process for NFETs (FIGS. 25B-27B)), the epitaxial S/D features 146, 147 are grown with different heights. In one exemplary embodiment, the epitaxial S/D feature 147 at the first device region 103 may have a first height H1 and the epitaxial S/D feature 146 at the second device region 105 may have second height H2 that is shorter than the first height H1. Thereafter, a contact etch stop layer (CESL) 162 and an interlayer dielectric (ILD) layer 164 are formed over the semiconductor device structure 300, in a similar fashion as discussed above with respect to FIGS. 9A-9B to 12A-12B.

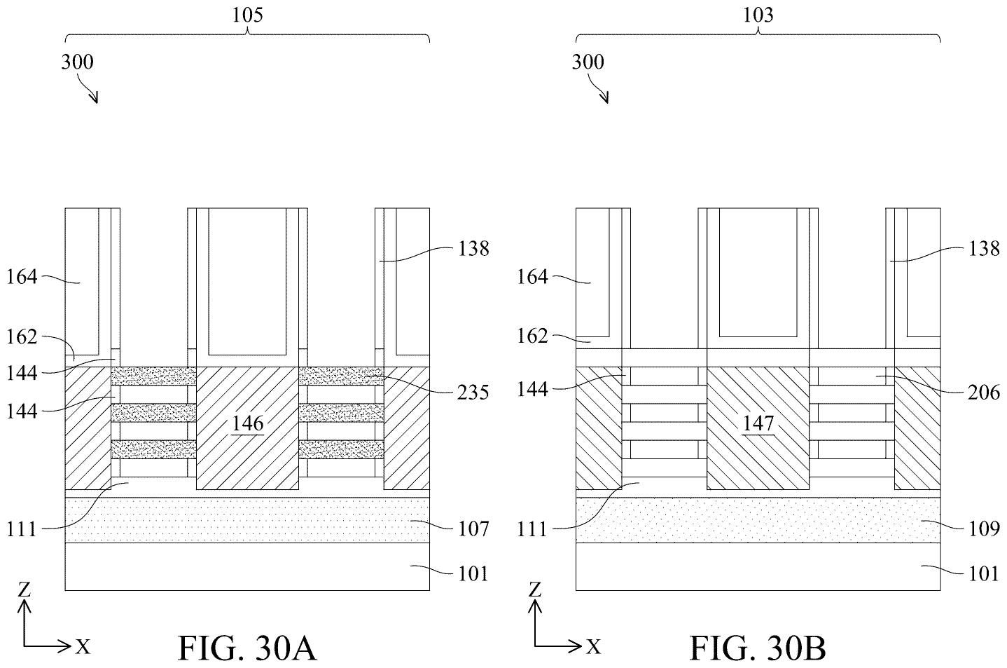

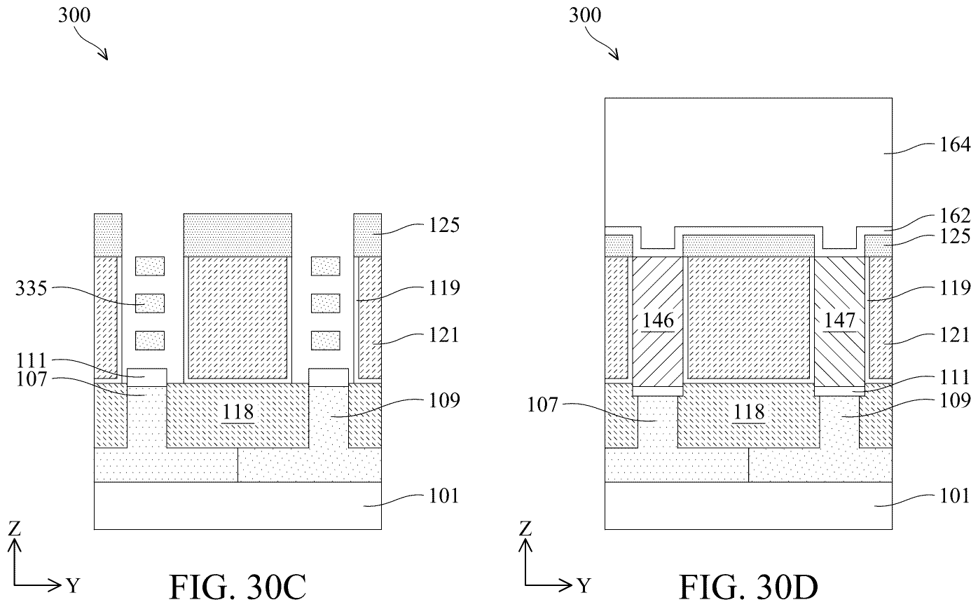

In FIGS. 30A-30D, after the ILD layer 164 has been formed, a planarization operation, such as CMP, is performed on the semiconductor device structure 300 to remove portions of the ILD layer 164, the CESL 162, and the mask layer 136 until the sacrificial gate electrode layer 134 is exposed. The sacrificial gate electrode layer 134 at the first device region 103 has a first height and the sacrificial gate electrode layer 134 at the second device region 105 has a second height that is greater than the first height. The sacrificial gate structure 130, the cladding layer 117, the first semiconductor layers 206, and the second semiconductor layers 208 are then removed from the semiconductor device structure 300 at the first and second device regions 103, 105, respectively. The etchant is selective so that the etch stop layer 111 is not substantially etched during removal of the first and second semiconductor layers 206, 208. Upon removal of the sacrificial gate structure 130 and the first semiconductor layers 206, a portion of the filling layers 335 at the second device region 105 is exposed. Likewise, a portion of the first semiconductor layers 206 at the first device region 103 is exposed after removing the sacrificial gate structure 130 and the second semiconductor layers 208.

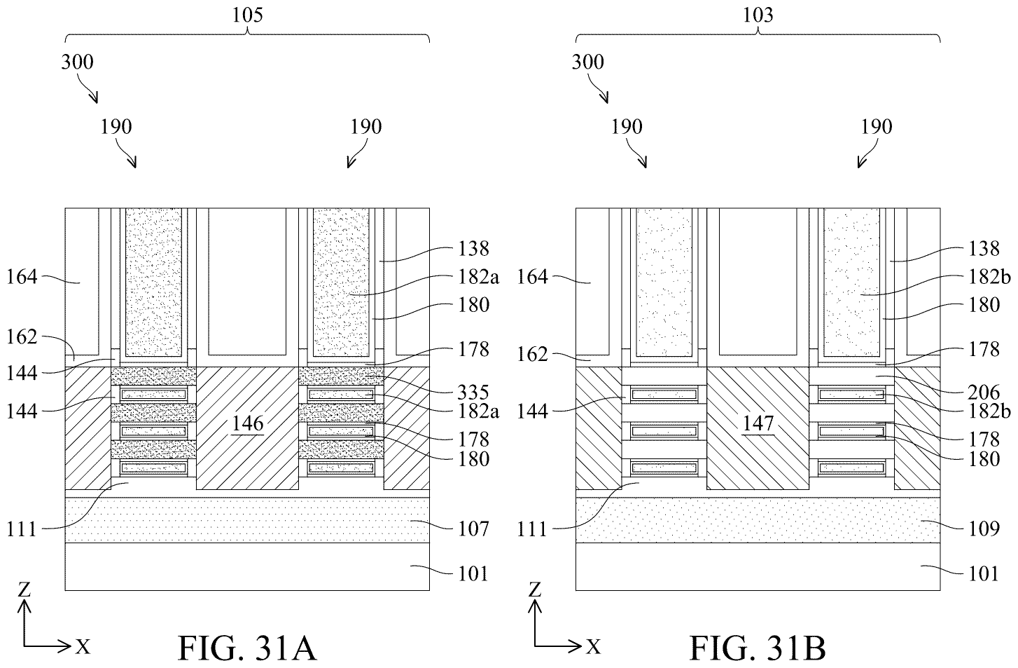

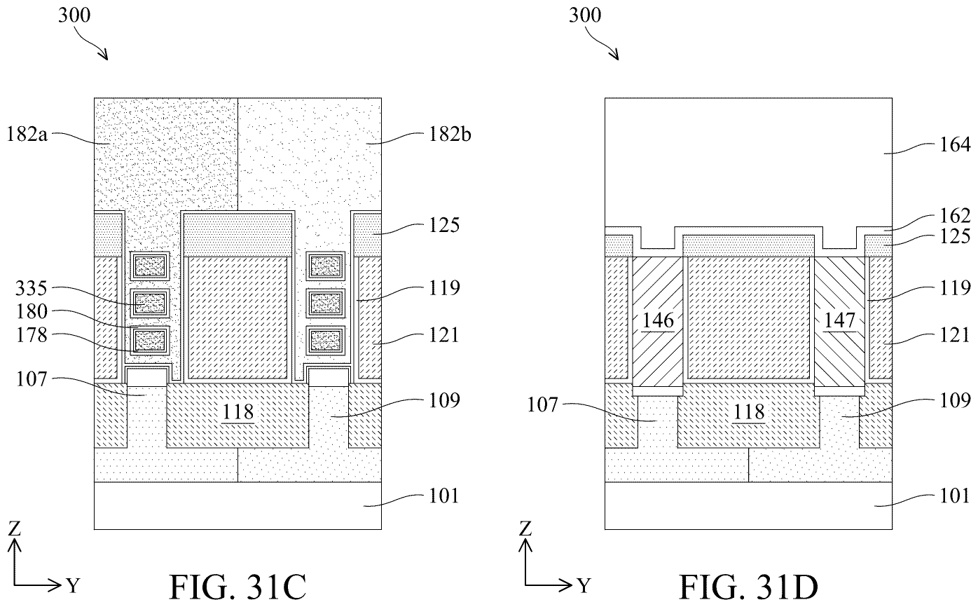

In FIGS. 31A-31D, replacement gate structures 190 are formed in the region provided by removal of the cladding layers 117 and the second semiconductor layers 208 at the first and second device regions 103, 105. The replacement gate structures 190 each includes an interfacial layer (IL) 178, a gate dielectric layer 180, and a gate electrode layer 182a/182b, and may be formed in a similar manner as discussed above with respect to FIGS. 15A-15D. Thereafter, the gate electrode layer 182a and the gate electrode layer 182b are planarized by a planarization process.

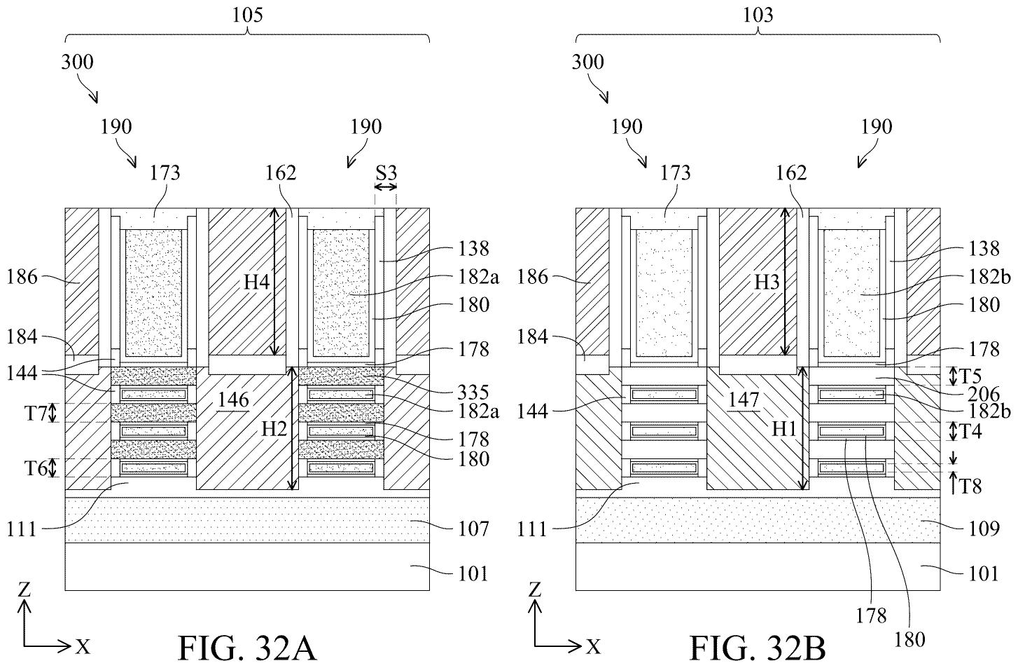

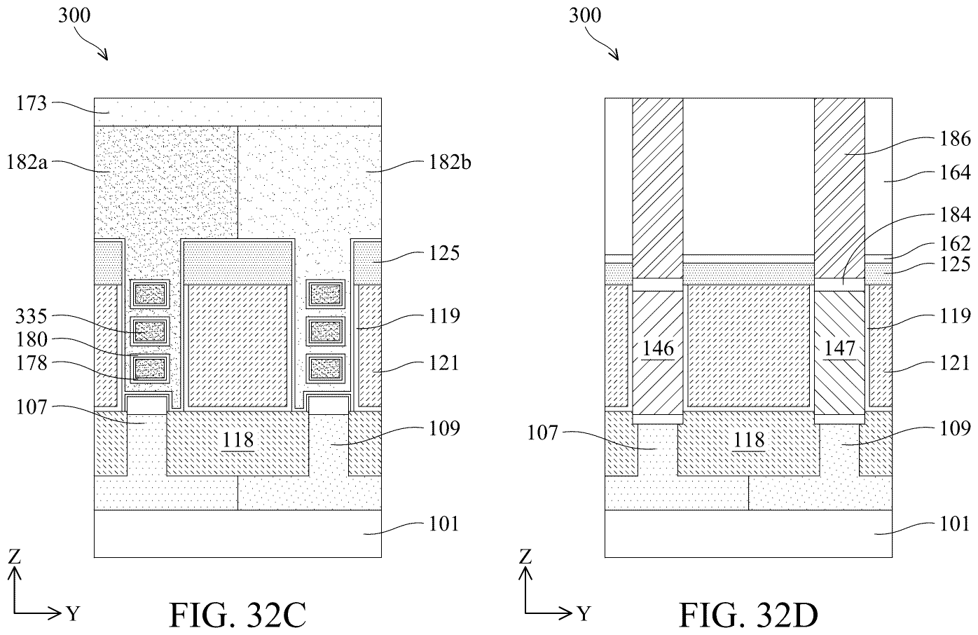

In FIGS. 32A-32D, the gate electrode layer 182a, 182b may be subject to one or more metal gate etching back (MGEB) processes so that the top surfaces of the gate electrode layer 182a, 182b and the gate dielectric layer 180 are recessed to a level below the top surface of the gate spacers 138. A self-aligned contact layer 173 is then formed over the gate electrode layer 182a, 182b and the gate dielectric layer 180 between the gate spacers 138. After formation of the self-aligned contact layer 173, contact openings are formed through the ILD layer 164 and the CESL 162 to expose the epitaxial S/D feature 146, 147. A silicide layer 184 is then formed on the S/D epitaxial feature 146, 147, and a S/D contact 186 is formed in the contact opening on the silicide layer 184. Any deposited material outside of the contact openings may be removed using a planarization process, such as a CMP.

As can be seen in FIGS. 32A and 32B, NFETs at the first device region 103 and PFETs at the second device region 105 are formed with staggered channels and different S/D contact heights due partially to patterning process for NFETs (i.e., FIGS. 25B-27B) and the fact that different semiconductor layers were removed for channel layers (i.e., FIGS. 30A and 30B). The channel layers of NFETs at the first device region 103 and PFETs at the second device region 105 are not aligned. Particularly, the topmost channel layer at the first device region 103 (i.e., the topmost first semiconductor layer 206 of the stack of the semiconductor layers 204 (FIG. 25B)) is at a first elevation, and the topmost channel layer at the second device region 105 (i.e., the topmost filling layer 335 of the stack of the semiconductor layers 204 (FIG. 29A)) is at a second elevation that is different (e.g., lower) than the first elevation, resulting in different metal-gate heights on the topmost channel layer at the first and second device regions 103, 105. Stated differently, the bottom surface 182b-1 of the gate electrode layer 182b at the first device region 103 is at an elevation different (e.g., higher) than the bottom surface 182a-1 of the gate electrode layer 182a at the second device region 105.

The two opposing ends or edge portions of the topmost channel layer (i.e., first semiconductor layer 206) at the first device region 103 have a first side in contact with the dielectric spacer 144 and a second side in contact with the gate spacer 138. The two opposing ends or edge portions of the topmost channel layer (i.e., filling layer 335) at the second device region 105 is disposed between and in contact with the dielectric spacer 144. As such, the gate-to-source/drain parasitic capacitance of the PMOS devices is minimized due to the increased dielectric body combining the topmost dielectric spacer 144 and the CESL 162 (represented by distance S3).

The epitaxial S/D features 147 at the first device region 103 have a first height H1, and the epitaxial S/D features 146 at the second device region 105 have a second height H2 less than the first height H1. Correspondingly, the S/D contacts 186 at the first device region 103 have a third height H3 and the S/D contacts 186 at the second device region 105 have a fourth height H4 that is greater than the third height H3. While the etch stop layers 111 at the first and second device regions 103, 105 are at the same elevation, the channel layers (i.e., first semiconductor layers 206) above the etch stop layer 111 at the first device region 103 have a first number, and the channel layers (i.e., filling layers 335) above the etch stop layer 111 at the second device region 105 have a second number different (e.g., greater) than the first number. As such, the channel mobility for PMOS devices is enhanced due to the strained Ge being used as a channel layer, and the channel mobility for NMOS devices is also enhanced due to the increased number of channel layers.

In some embodiments, the dielectric spacer 144 at the first device region 103 may have a thickness T4 and each first semiconductor layer 206 at the first device region 103 may have a thickness T5 that is substantially the same as the thickness T1. The dielectric spacer 144 at the second device region 105 may have a thickness T6 and each filling layer 335 at the second device region 105 may have a thickness T7 that is less than the thickness T6.

In some embodiments, the thickness T4 is greater than the thickness T5 by about 0.1 nm to about 3 nm. If the thickness T4 is greater than about 3 nm, the thickness of the channel layer (i.e., first semiconductor layers 206) may be reduced, resulting in an increased gate-to-source/drain parasitic capacitance for the NMOS devices.

In some embodiments, the first semiconductor layers 206 may be consumed when removing the second semiconductor layers 208 for replacement gate structure. In such cases, the gate electrode layer 182b at the first device region 103 may have a thickness T8 that is substantially the same as the thickness T5.

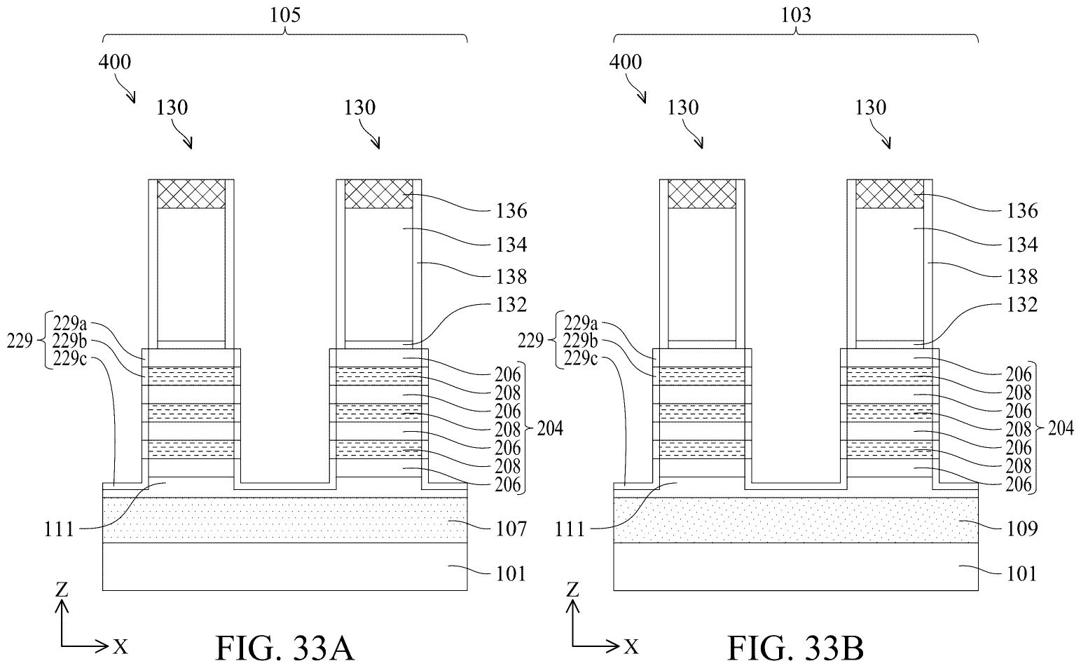

FIGS. 33A-33B to 40A-40D show exemplary processes for manufacturing a semiconductor device structure 400 according to one another embodiment of the present disclosure. The embodiment of FIGS. 33A-33B to 40A-40D is similar to the embodiment shown in FIGS. 25A-25B to 32A-32D except that NFET channels are strained silicon. FIGS. 33A and 33B illustrate a stage of the semiconductor device structure 400 after oxide layers 229 are formed on the exposed surfaces of the first semiconductor layers 206, the second semiconductor layers 208, and the etch stop layer 111, respectively, such as the semiconductor device structure 200 shown in FIGS. 20A and 20B.

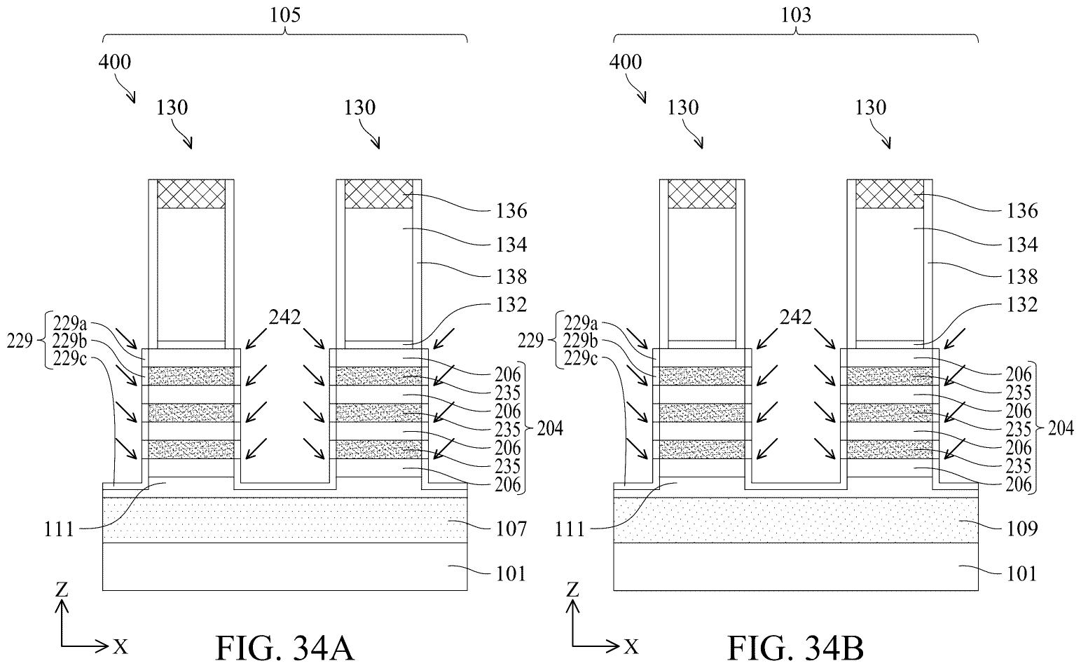

In FIGS. 34A and 34B, the second semiconductor layers 208 are removed, and a filling layer 235, such as the filling layer 135, is refilled in the region where the second semiconductor layers 208 were removed, in a similar fashion as discussed above with respect to FIGS. 21A and 21B. Due to lattice mismatch between germanium and silicon, the first semiconductor layers 206 at the first device region 103 are formed with strain (i.e., strained silicon). As a result, the channel mobility for NMOS transistor devices (e.g., N-type gate all around transistors) is improved.

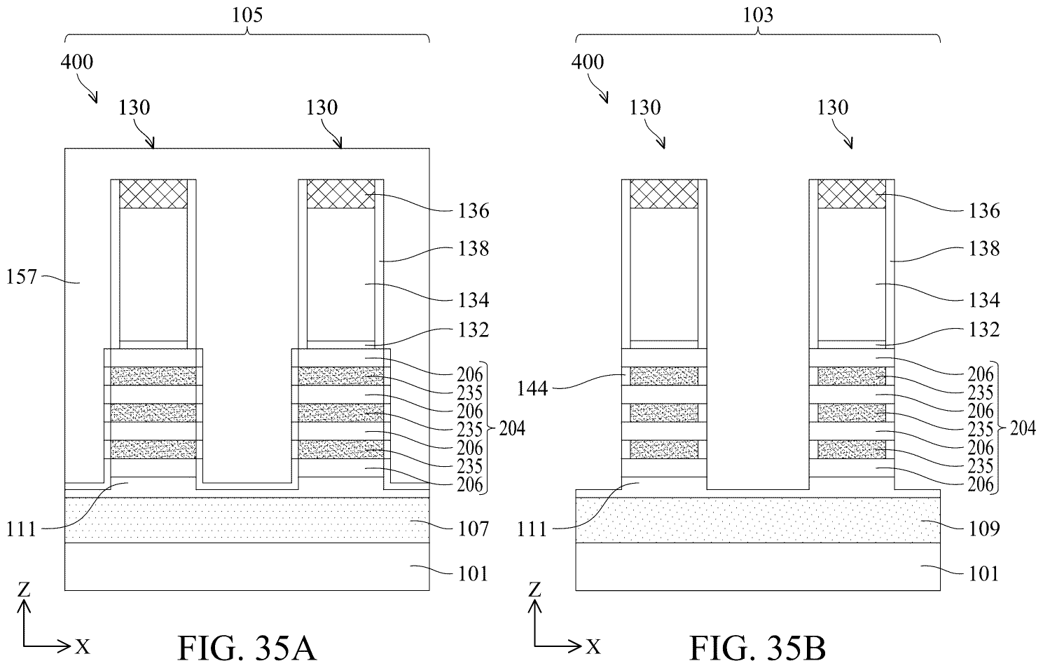

In FIGS. 35A and 35B, a hard mask layer 157, such as the hard mask layer 137 discussed above, is deposited on exposed surfaces of the semiconductor device structure 400 at the first and second device regions 103, 105. The hard mask layer 157 at the first device region 103 is patterned to expose areas over the P-type well 109 where N-type devices are to be formed. The hard mask layer 157 may be formed in a similar fashion as discussed above with respect to FIG. 25B. The oxide layers 229 at the first device region 103 are removed, and inner spacers 144 are formed by replacing edge portions of the filling layers 235 with a dielectric layer, in a similar fashion as discussed above with respect to FIGS. 22A and 22B.

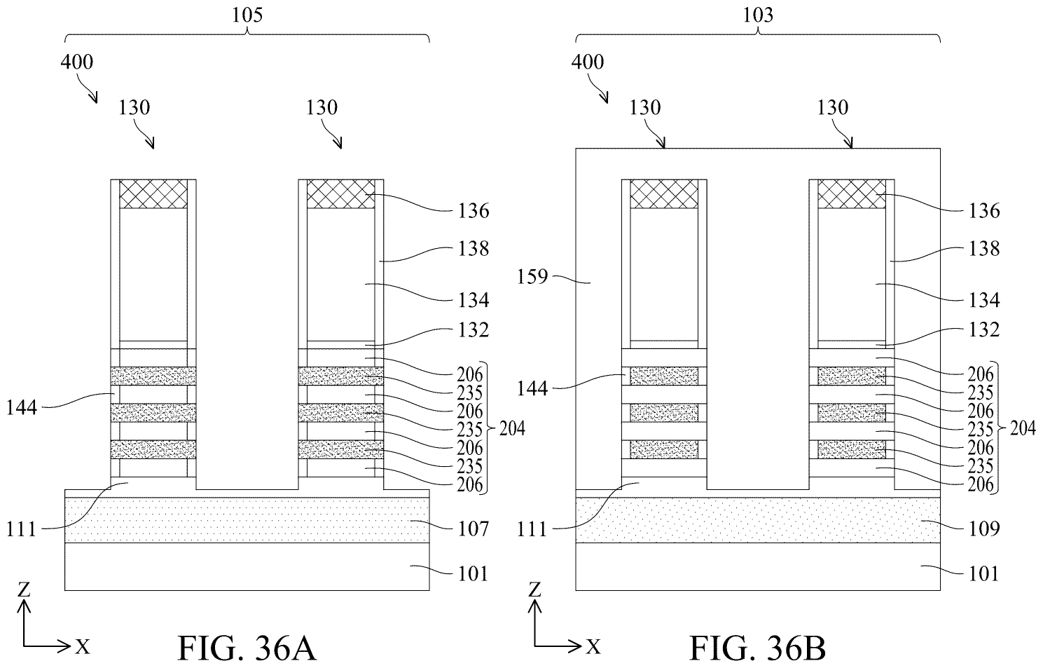

In FIGS. 36A and 36B, after the inner spacers 144 at the first device region 103 are formed, a hard mask layer 159, such as the hard mask layer 137, is deposited on exposed surfaces of the semiconductor device structure 400 at the first device region 103. Thereafter, a photolithography process is performed to pattern the hard mask layer 157 to expose processing areas at the second device region 105. Then, the oxide layers 229 at the second device region 105 are removed, and edge portions of each first semiconductor layer 206 of the stack of semiconductor layers 204 at the second device region 105 are removed horizontally along the X direction. The removal of the edge portions of the first semiconductor layers 206 forms cavities, which are then filled with a dielectric material to form inner spacers 144, in a similar fashion as discussed above.

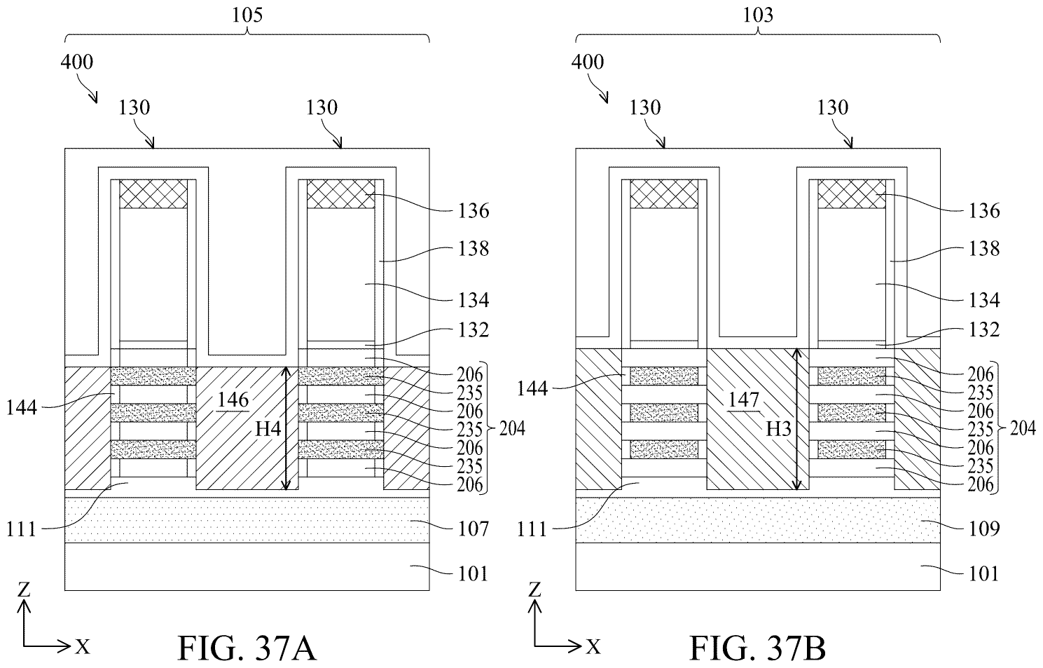

In FIGS. 37A and 37B, the hard mask layer 159 is removed, and epitaxial S/D features 146, 147 are formed in the source/drain (S/D) regions at the first and second device regions 103, 105. The epitaxial S/D features 146, 147 may grow laterally from the filling layers 235 and the first semiconductor layers 206, respectively. The epitaxial S/D features 146, 147 may form facets corresponding to crystal planes of the material of the filling layers 235 and the first semiconductor layers 206. Due to different growth rates on different materials and the fact that the first semiconductor layers 206 at the first device region 103 and the filling layers 335 at the second device region 105 are arranged at different heights, the epitaxial S/D features 146, 147 are grown with different heights. In one exemplary embodiment, the epitaxial S/D feature 147 at the first device region 103 may have a first height H3 and the epitaxial S/D feature 146 at the second device region 105 may have second height H4 that is shorter than the first height H3. Thereafter, a contact etch stop layer (CESL) 162 and an interlayer dielectric (ILD) layer 164 are sequentially formed over the semiconductor device structure 400, in a similar fashion as discussed above with respect to FIGS. 9A-9B to 12A-12B.

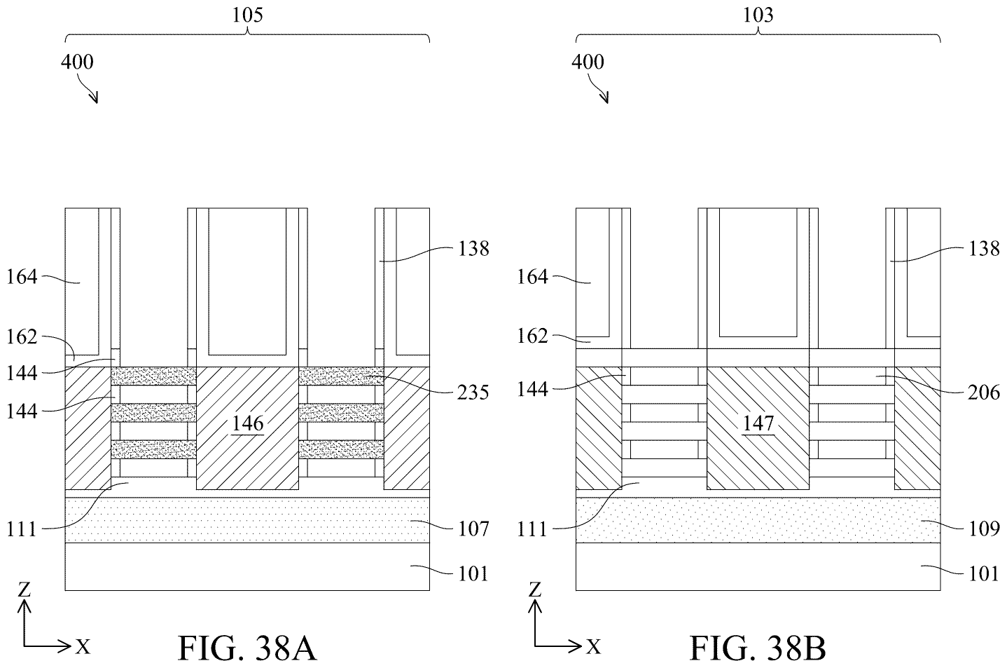

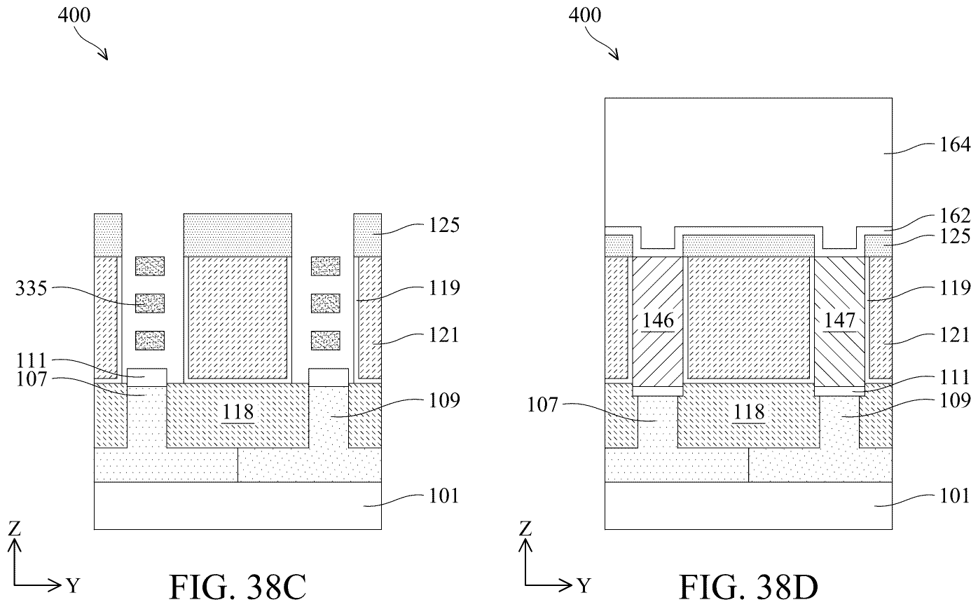

In FIGS. 38A-38D, after the ILD layer 164 has been formed, a planarization operation, such as CMP, is performed on the semiconductor device structure 400 to remove portions of the ILD layer 164, the CESL 162, and the mask layer 136 until the sacrificial gate electrode layer 134 is exposed. The sacrificial gate structure 130, the cladding layer 117, the first semiconductor layers 206, and the second semiconductor layers 208 are then removed from the semiconductor device structure 400 at the first and second device regions 103, 105, respectively. The etchant is selective so that the etch stop layer 111 is not substantially etched during removal of the first and second semiconductor layers 206, 208. Upon removal of the sacrificial gate structure 130 and the first semiconductor layers 206, a portion of the filling layers 335 at the second device region 105 is exposed. Likewise, a portion of the first semiconductor layers 206 at the first device region 103 is exposed after removing the sacrificial gate structure 130 and the second semiconductor layers 208.

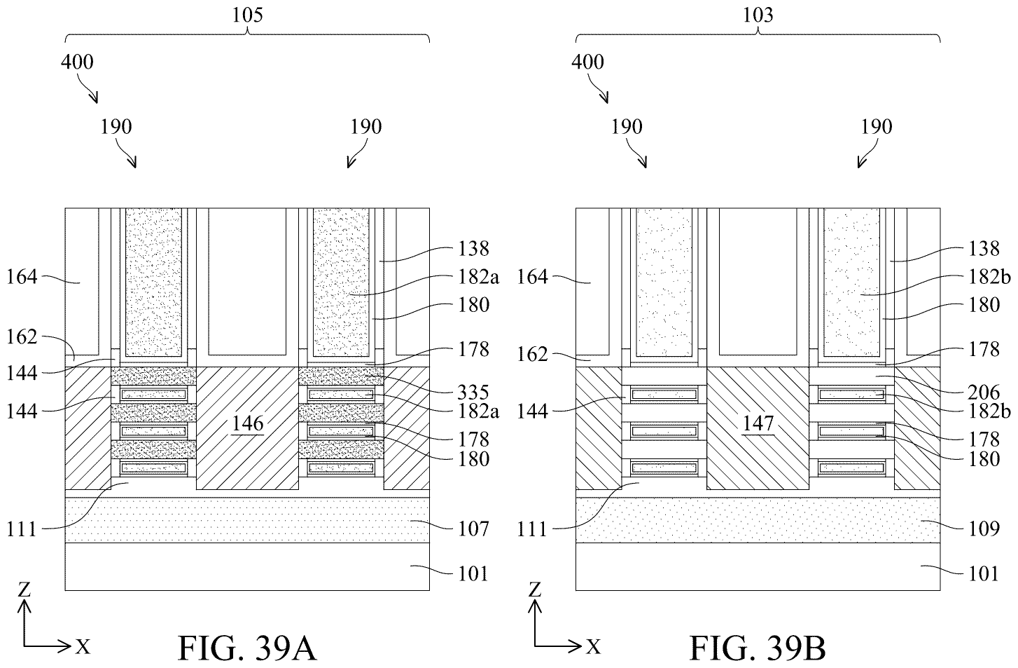

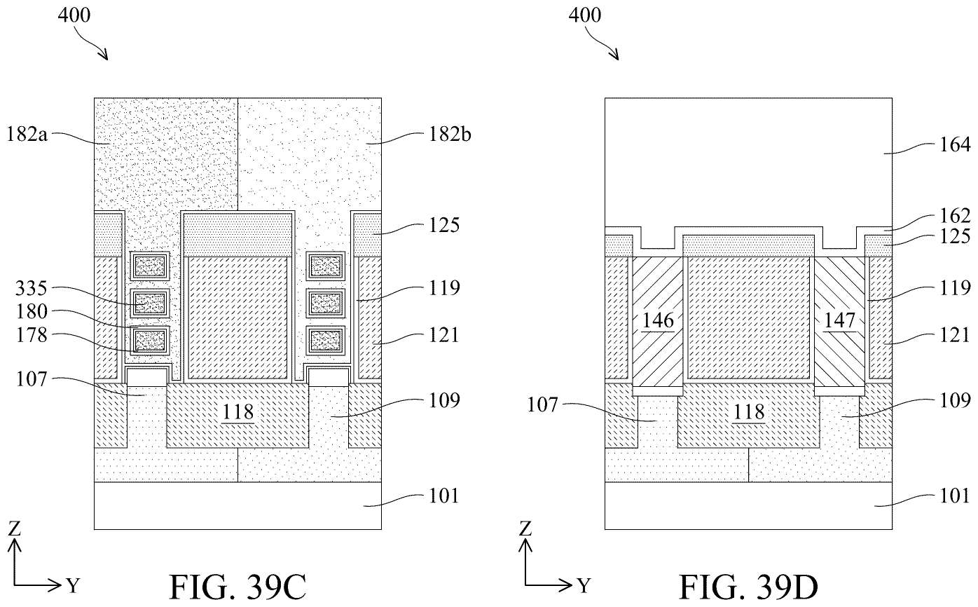

In FIGS. 39A-39D, replacement gate structures 190 are formed in the region provided by removal of the cladding layers 117 and the second semiconductor layers 208 at the first and second device regions 103, 105. The replacement gate structures 190 each includes an interfacial layer (IL) 178, a gate dielectric layer 180, and a gate electrode layer 182a/182b, and may be formed in a similar manner as discussed above with respect to FIGS. 15A-15D. Thereafter, the gate electrode layer 182a and the gate electrode layer 182b are planarized by a planarization process.

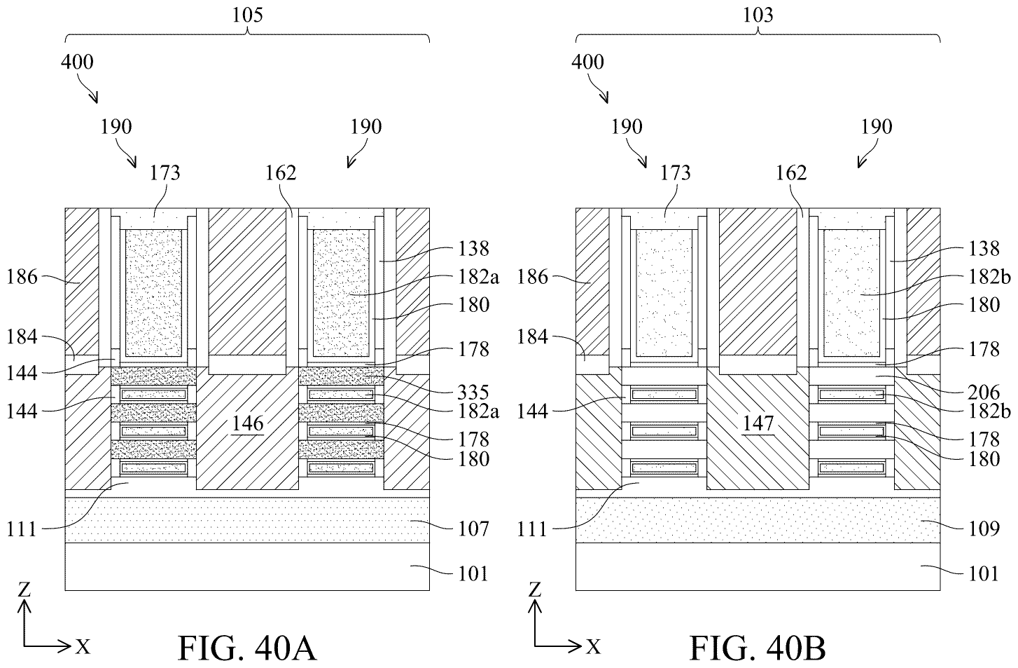

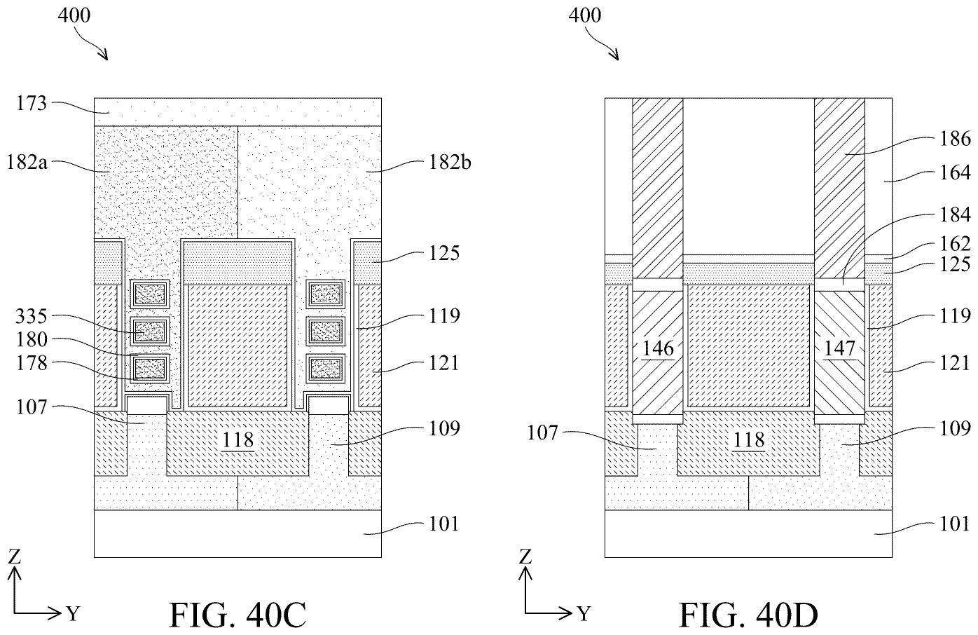

In FIGS. 40A-40D, the gate electrode layer 182a, 182b may be subject to one or more metal gate etching back (MGEB) processes so that the top surfaces of the gate electrode layer 182a, 182b and the gate dielectric layer 180 are recessed to a level below the top surface of the gate spacers 138. A self-aligned contact layer 173 is then formed over the gate electrode layer 182a, 182b and the gate dielectric layer 180 between the gate spacers 138. After formation of the self-aligned contact layer 173, contact openings are formed through the ILD layer 164 and the CESL 162 to expose the epitaxial S/D feature 146, 147. A silicide layer 184 is then formed on the S/D epitaxial feature 146, 147, and a S/D contact 186 is formed in the contact opening on the silicide layer 184. Any deposited material outside of the contact openings may be removed using a planarization process, such as a CMP.

The semiconductor device structure 400 may then undergo further complementary metal oxide semiconductor (CMOS) and/or back-end-of-line (BEOL) processes to form various features such as transistors, contacts/vias, interconnect metal layers, dielectric layers, passivation layers, etc.

Various embodiments or examples described herein provide improved semiconductor device structures using a strained germanium material as a channel layer to enhance channel mobility for PFETs, using germanium material, normal silicon, or strained silicon material as a channel layer to enhance channel mobility for NFETs. In some embodiments, a topmost channel layer (e.g., strained Ge layer) of NFETs and/or PFETs has its both sides in contact with an inner spacer, making a topmost inner spacer disposed between a gate electrode layer and a S/D contact. As a result, the gate-to-source/drain parasitic capacitance is minimized due to the increased dielectric body combining the topmost inner spacer and an immediately adjacent layer (e.g., contact etch stop layer).

An embodiment is a semiconductor device structure. The semiconductor device structure includes a first transistor comprising a plurality of first semiconductor layers vertically stacked, each first semiconductor layer being surrounded by a first gate electrode layer, a second transistor disposed over the first transistor, the second transistor comprising a plurality of second semiconductor layers vertically stacked, each second semiconductor layer being surrounded by a second gate electrode layer different from the first gate electrode layer, an isolation layer disposed between a topmost first semiconductor layer of the first transistor and a bottommost second semiconductor layer of the second transistor, the isolation layer comprising a dielectric material, a first source/drain feature in contact with the first semiconductor layers and a portion of the isolation layer, and a second source/drain feature disposed over the first source/drain feature and in contact with the second semiconductor layers and a portion of the isolation layer, wherein the topmost first semiconductor layer and the bottommost second semiconductor layer comprise alkaline elements diffused from a sacrificial layer comprising a semiconductor metal oxide.

Another embodiment is a method for forming a semiconductor device structure. The method includes forming a sacrificial layer comprising a semiconductor metal oxide between a first stack of layers and a second stack of layers disposed over the first stack of layers, wherein the first stack of layers comprises a plurality of first semiconductor layers and a plurality of second semiconductor layers alternatingly stacked, and the second stack of layers comprises a plurality of third semiconductor layers and a plurality of fourth semiconductor layers alternatingly stacked, forming a sacrificial gate structure over a portion of the second stack of layers, removing portions of the first and second stack of layers not covered by the sacrificial gate structure, removing the sacrificial layer to form a cavity, wherein alkaline elements from the sacrificial layer diffuse into the first and third semiconductor layers adjacent to the sacrificial layer; filling the cavity with a dielectric material to form an isolation layer, and forming a first source/drain feature and a second source/drain feature on opposing sides of the sacrificial gate structure, wherein the first source/drain feature is disposed below the second source/drain feature, and the first and second source/drain features are in contact with the isolation layer, the first semiconductor layers, and the third semiconductor layers.

A further embodiment is a method for forming a semiconductor device structure. The method includes forming a plurality of fin structures from a substrate, each fin structure comprising a plurality of first semiconductor layers and a plurality of second semiconductor layers alternatingly stacked, forming a sacrificial layer comprising a semiconductor metal oxide between two immediately adjacent first semiconductor layers, diffusing metal elements from the sacrificial layer into the first semiconductor layers immediately adjacent to the sacrificial layer, replacing the sacrificial layer with a dielectric material to form an isolation layer, forming a first source/drain feature in contact with a lower portion of the isolation layer and the first semiconductor layers below the isolation layer, and forming a second source/drain feature in contact with an upper portion of the isolation layer and the first semiconductor layers above the isolation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first transistor comprising a plurality of first semiconductor layers vertically stacked, each first semiconductor layer being surrounded by a first gate electrode layer; a second transistor disposed over the first transistor, the second transistor comprising a plurality of second semiconductor layers vertically stacked, each second semiconductor layer being surrounded by a second gate electrode layer different from the first gate electrode layer;
an isolation layer disposed between a topmost first semiconductor layer of the first transistor and a bottommost second semiconductor layer of the second transistor, the isolation layer comprising a dielectric material;
a first source/drain feature in contact with the first semiconductor layers and a portion of the isolation layer; and
a second source/drain feature disposed over the first source/drain feature and in contact with the second semiconductor layers and a portion of the isolation layer, wherein the topmost first semiconductor layer and the bottommost second semiconductor layer comprise alkaline elements diffused from a sacrificial layer comprising a semiconductor metal oxide.

2. The semiconductor device structure of claim 1, wherein the semiconductor metal oxide comprises an alkaline earth titanate selected from the group consisting of strontium titanate (SrTiO3), barium titanate (BaTiO3), barium strontium titanate (BaSrTiO3), and lanthanum titanate (LaTiO3).

3. The semiconductor device structure of claim 1, wherein the alkaline elements comprise strontium (Sr) or titanium (Ti).

4. The semiconductor device structure of claim 1, wherein the topmost first semiconductor layer has a first element concentration of alkaline elements at an interface with the isolation layer and a second element concentration at a center region, the first element concentration being greater than the second element concentration.

5. The semiconductor device structure of claim 1, wherein the isolation layer has a thickness greater at an edge than at a center, corresponding to a profile of the sacrificial layer.

6. The semiconductor device structure of claim 1, further comprising:
a dielectric material disposed between the first source/drain feature and the second source/drain feature, wherein a top surface of the dielectric material is at an elevation between a top surface and a bottom surface of the isolation layer.

7. The semiconductor device structure of claim 1, wherein the first gate electrode layer comprises a p-type gate electrode material and the second gate electrode layer comprises an n-type gate electrode material.

8. The semiconductor device structure of claim 1, further comprising:
dielectric spacers disposed adjacent to the first and second semiconductor layers, the dielectric spacers comprising the same material as the isolation layer.

9. The semiconductor device structure of claim 1, wherein the isolation layer comprises a material selected from the group consisting of SiON, SiCN, SiOC, SiOCN, and SiN.

10. The semiconductor device structure of claim 1, further comprising:
a high-k dielectric layer surrounding the first and second semiconductor layers and in contact with the isolation layer.

11. A method for forming a semiconductor device structure, comprising:
forming a sacrificial layer comprising a semiconductor metal oxide between a first stack of layers and a second stack of layers disposed over the first stack of layers, wherein the first stack of layers comprises a plurality of first semiconductor layers and a plurality of second semiconductor layers alternatingly stacked, and the second stack of layers comprises a plurality of third semiconductor layers and a plurality of fourth semiconductor layers alternatingly stacked;
forming a sacrificial gate structure over a portion of the second stack of layers;
removing portions of the first and second stack of layers not covered by the sacrificial gate structure;
removing the sacrificial layer to form a cavity, wherein alkaline elements from the sacrificial layer diffuse into the first and third semiconductor layers adjacent to the sacrificial layer;
filling the cavity with a dielectric material to form an isolation layer; and
forming a first source/drain feature and a second source/drain feature on opposing sides of the sacrificial gate structure, wherein the first source/drain feature is disposed below the second source/drain feature, and the first and second source/drain features are in contact with the isolation layer, the first semiconductor layers, and the third semiconductor layers.

12. The method of claim 11, wherein the semiconductor metal oxide comprises an alkaline earth titanate selected from the group consisting of strontium titanate (SrTiO3), barium titanate (BaTiO3), barium strontium titanate (BaSrTiO3), and lanthanum titanate (LaTiO3).

13. The method of claim 11, wherein removing the sacrificial layer comprises using a fluoride-based etchant selected from the group consisting of hydrogen fluoride (HF), hydroboron tetrafluoride (HBF4), and ammonium fluoride (NH4F).

14. The method of claim 11, further comprising:
forming dielectric spacers in cavities formed by removing edge portions of the second and fourth semiconductor layers, wherein the dielectric spacers and the isolation layer comprise the same dielectric material.

15. The method of claim 11, wherein the sacrificial layer is formed by a molecular beam epitaxy (MBE) process at a temperature range of about 400 degrees Celsius to about 800 degrees Celsius.

16. The method of claim 11, further comprising:
removing the sacrificial gate structure and the second and fourth semiconductor layers to expose portions of the first and third semiconductor layers;
forming an interfacial layer on the exposed portions of the first and third semiconductor layers; and
forming a high-k dielectric layer over the interfacial layer and the isolation layer.

17. A method for forming a semiconductor device structure, comprising:
forming a plurality of fin structures from a substrate, each fin structure comprising a plurality of first semiconductor layers and a plurality of second semiconductor layers alternatingly stacked;
forming a sacrificial layer comprising a semiconductor metal oxide between two immediately adjacent first semiconductor layers;
diffusing metal elements from the sacrificial layer into the first semiconductor layers immediately adjacent to the sacrificial layer;
replacing the sacrificial layer with a dielectric material to form an isolation layer;
forming a first source/drain feature in contact with a lower portion of the isolation layer and the first semiconductor layers below the isolation layer; and
forming a second source/drain feature in contact with an upper portion of the isolation layer and the first semiconductor layers above the isolation layer.

18. The method of claim 17, wherein the first semiconductor layers immediately adjacent to the isolation layer have a gradient profile of the metal elements, with a higher concentration at an interface with the isolation layer than at a center region.

19. The method of claim 17, further comprising:
forming a dielectric material between the first and second source/drain features, wherein the dielectric material is recessed to a level below the first semiconductor layers above the isolation layer.

20. The method of claim 17, wherein replacing the sacrificial layer comprises selectively etching the sacrificial layer using a hydrogen fluoride-based etchant without substantially affecting the first and second semiconductor layers.
